(19) United States
(12) Patent Application Publication
(10) Pub. No.: US 2010/0007444 A1
(43) Pub. Date: Jan. 14, 2010

(54) GHz Surface Acoustic Resonators in RF-CMOS

(76) Inventors: Anis Nurashikin Nordin, Shah Alam (MY); Mona Zaghloul, Bethesda, MD (US)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(21) Appl. No.: 12/405,503

(22) Filed: Mar. 17, 2009

Related U.S. Application Data
(63) Continuation-in-part of application No. 11/738,460, filed on Apr. 20, 2007.
(60) Provisional application No. 60/793,328, filed on Apr. 20, 2006.

(51) Int. Cl. H03H 9/25; H04R 31/00; H04R 17/00

(52) U.S. Cl. 333/195; 29/594; 29/25.35

(57) ABSTRACT

An improved SAW resonator fabricated using RF-CMOS technology is disclosed. The SAW resonator is capable of a resonant frequency of from about 1 GHz to about 3.12 GHz. Several different embodiments namely both single and double port resonators implemented in standard CMOS (0.6 μm) and RF-CMOS (0.18 μm) technologies are presented.

### CROSS REFERENCE TO RELATED APPLICATIONS

This application is a continuation-in-part application and claims priority benefit of the earlier filing date under 35 USC 120 of U.S. patent application Ser. No. 11/738,460 filed 20 Apr. 2007, the content of which is incorporated herein in its entirety, which claims priority under 119(e) to U.S. 60/793,328 filed 20 Apr. 2006.

### STATEMENT REGARDING FEDERALLY SPONSORED RESEARCH

This was supported in part by NSF under Grant 0225431.

### NAMES OF PARTIES TO A JOINT RESEARCH AGREEMENT

n/a

### REFERENCE TO A SEQUENCE LISTING

n/a

### BACKGROUND

1. Field of the Invention

The present invention relates to the field of surface acoustic wave (SAW) resonators, and specifically to improvements in the use of mainstream RF-CMOS technology to fabricate submicron width, high aspect ratio interdigital transducers (IDTs) and reflectors which allow the RF-CMOS SAW resonator to achieve GHz frequencies with high quality factors. Compatibility of these SAW resonators with the standard RF-CMOS process technology will greatly simplify the integration of these devices together with RF-circuits on the same chip. This technological development will lead to performance improvement of these CMOS devices in the RF-range due to the elimination of lossy wire-bonds, parasitic and attenuation normally plaguing discrete RF-components. Such resonators, typically targeted for telecommunication applications require low insertion losses and high quality factors. This work describes the post-CMOS micromachining processes required to realize this novel device namely reactive-ion-etching, zinc-oxide deposition and patterning using lithography and wet-etching. It also describes progression of several different devices in standard CMOS (0.6 ┌m) and RF-CMOS (0.18 ┌m) process technologies. Each fabricated device can be modeled using an equivalent RLC circuit model, which facilitates simulation with RF-circuits. Two different novel techniques has been included in this device in the pursuit of low insertion losses and high quality factors; namely increase in the reflector height using stacked CMOS metal-oxide layers and matching networks. The former drastically improves the quality factor while the latter reduces the insertion losses dramatically. The SAW resonators are equipped with temperature compensation capabilities, implemented on-chip using a micro-oven. Finally, the application of the CMOS-SAW resonator as an RF-Oscillator is also demonstrated.

2. Description of the Prior Art

Recent fabrication technological developments in the complementary metal-oxide semiconductor (CMOS) technology have led to a marked improvement in the performance of these CMOS devices in the RF range. Previously, mainstream CMOS devices have been considered as having poor RF performance compared to its silicon bipolar and compound counterparts, making it only suitable for analog and digital large scale devices. The performance enhancement of RF-CMOS devices is largely attributed to the aggressive downsizing of the CMOS transistors' gate widths to 0.25 ┌m and 0.18 ┌m, leading to improvement in the transistors cutoff frequency (f_{T}), and maximum frequency (fₘₐₓ). The increased capabilities of these CMOS devices have led to the successful design and implementation of major RF transceiver building blocks such as low-noise amplifiers (LNAs), power amplifiers, mixers and local oscillators (LOs). With its popularity in the field of RFICs, especially as a RF transceiver building block, it seems logical that RF SAW filters be implemented using the same highly reliable, low-cost CMOS fabrication method. Although typically optimized for integrated circuits, a wide variety of novel MEMS devices have been successfully implemented using CMOS fabrication techniques. Utilizing micromachining processes implemented subsequent to the standard CMOS fabrication, micro-sensors, microwave filters, micro-fluidic elements and micro-hotplates can be manufactured using this technology.

CMOS is the technology of choice due to its low-cost, high reliability, high yield and very precise fabrication techniques. A major fabrication challenge of manufacturing nm wide IDTs is solved with the implementation of such IDTs using standard IC processing techniques. Capitalizing on the manufacturing reliability of commercial IC foundries, high resolution IDTs can be fabricated, creating GHz range SAW resonators. Complete integration of the resonators with the RF circuits using the same CMOS fabrication process eliminates the need for lossy wire-bonds to connect the passive device to the circuits, reducing the parasitics, attenuation and thus improving the performance of the device. The integrated system has numerous advantages namely small size, reduced costs and noise reduction. It also simplifies packaging, allowing both the filters and the integrated circuits to be placed on a single die and encapsulated in a single package. Another key advantage of integration is miniaturization of the device through reduction of component count, leading to lower required battery power, a precious commodity in mobile-RF systems.

Acoustic wave sensors use a detection arrangement that is based on perturbations to mechanical or acoustic waves. As an acoustic wave propagates through or on the surface of the acoustic wave sensor material, any changes to the physical or chemical characteristics of the wave path may affect the velocity and/or amplitude of the acoustic wave. These changes may be correlated to the corresponding physical, chemical, or biological quantities being measured to provide sensing.

There may be various sensors, using fiber optics, chemical interactions, and various fluorescence approaches. Such sensors may, however, have various weaknesses, such as, for example, low sensitivity, selectivity, or an inability to be hybridized or integrated into sensing chip technology. Acoustic wave (AW) sensors, however, may be better suited for use in biological and chemical detection. As discussed in D. S. Ballantine, R. M. White, S. J. Martin, A. J. Ricco, E. T. Zellers, G. C. Frye, H. Wohltjen, “Acoustic Wave Sensor—Theory, Design, and Physico-Chemical Applications”, Academic Press, (1997), acoustic wave sensors may use piezoelectric crystals, which may allow transduction between electrical and acoustic energies. The AW sensor may use piezoelectric material to convert a high frequency signal into an acoustic wave, and the higher frequency may enable the sensor to be more sensitive to surface perturbations.

Piezoelectric materials used for acoustic wave sensors may include quartz, lithium niobate (LiNbO₃), zinc oxide (ZnO), and others. Each of these materials may possess specific advantages and disadvantages, which may relate to, for example, cost, temperature dependence, attenuation, and propagation velocity. Such materials may, however, have varying transverse acoustic wave velocities, low electromechanical coupling coefficients, non-linear temperature coefficients, and may react chemically with the environment. (See the background information in C. Caliendo, G. Saggio, P. Veradi, E. Verona, “Piezoelectric AlN Film for SAW Device Applications”, Proc. IEEE Ultrasonic Symp., 249-252, (1992) and K. Kaya, Y. Kanno, I. Takahashi, Y. Shibata, T. Hirai, “Synthesis of AlN Thin Films on Sapphire Substrates by Chemical Vapor Deposition of AlCl.sub.3—NH.sub.3 Systems and Surface Acoustic Wave Properties”, Jpn. J. Appl. Phys. Vol. 35, 2782-2787, (1996) and G. Carlotti et al., “The Elastic Constants of Sputtered AlN Films”, Proc. IEEE Ultrasonic Symp., 353, (1992)).

Previously, creation of SAW devices has been complicated and, in the case of CMOS fabrication, it has been unworkable as the chip would be destroyed by the temperatures required to integrate the SAW device.

Patents related to SAW devices include: U.S. Pat. No. 5,864,260 entitled Monolithic SAW Duplexer; U.S. application Ser. No. 11/448,707 entitled Integrated filter including FBAR and SAW resonator and fabrication method; U.S. Pat. No. 5,581,141 entitled Surface acoustic wave filter; U.S. Pat. No. 4,683,395 entitled Surface acoustic wave device; U.S. Pat. No. 4,745,378 entitled Surface acoustic wave device; U.S. Pat. No. 5,448,126 entitled Surface acoustic wave-semiconductor composite device; and U.S. Pat. No. 6,198,197 entitled Surface acoustic wave element and electronic circuit using the same.

### SUMMARY OF THE INVENTION

Provided is an improved SAW resonator fabricated using RF-CMOS technology, wherein the SAW resonator is capable of a resonant frequency of from about 1 GHz to about 3.12 GHz.

In other preferred embodiments, the improved SAW resonator further comprises wherein the SAW resonator has a quality factor about 285 or greater, and/or the improved SAW resonator further comprises interdigital transducers and reflectors having submicron width, and/or the improved SAW resonator further comprises wherein the SAW resonator is miniature having length and width dimensions of less than about 500 μm, and/or length and width dimensions of less than about 300 μm.

In another preferred embodiment, there is provided a process for fabricating a GHz-capable SAW resonator device using standard RF-CMOS technology, comprising: i) removal of SiN and SiO₂ passivation layer using a two-step reactive-ion-etch and ii) depositing piezoelectric material on top of SAW resonator's electrodes, and iii) patterning the piezoelectric layer such that it only covers the resonator area using wet etching to reduce losses, wherein the SAW resonator electrodes are fabricated on the dielectric layer during CMOS fabrication and a reactive ion etch releases the SAW resonator electrodes from the dielectric layer before the piezoelectric material is deposited, wherein the SAW resonator is capable of a resonant frequency of from about 1 GHz to about 3.12 GHz.

In another preferred embodiment, there is provided a process for fabricating a GHz-capable SAW resonator device using standard CMOS technology, comprising: i) depositing piezoelectric material on top of SAW IDT's, and ii) performing a wet-etching of the piezoelectric material to expose the pads for bonding, wherein the SAW IDT's are patterned on the dielectic layer during CMOS fabrication and a reactive ion etch releases the IDT's from the dielectric layer before the piezoelectric material is deposited, wherein the SAW resonator is capable of a resonant frequency of from about 1 GHz to about 3.12 GHz.

Preferred processes also include: wherein the piezoelectric material is ZnO; and/or wherein the wet-etching uses a very dilute acid solution; and/or wherein the very dilute acid solution is a two acid mixture, wherein each acid of the two acid mixture is selected from the group consisting of acetic acid, hydrochloric acid, and phosphoric acid; and/or wherein the CMOS process sequence includes fabricating an isolation structure under the interdigital transducers and reflectors of the SAW resonator, wherein the isolation structure comprises a single, integrated metal shield and provides isolation from electromagnetic feed-through. It is also contemplated that SAW device products made by the processes herein are part of the inventive subject matter.

In another preferred embodiment, there is provided an integrated circuit chip having the SAW resonator described herein as an on-chip component. Further preferred embodiments include wherein the chip is a microprocessor, wherein the chip is a programmable integrated circuit, wherein the chip is a microelectromechanical system (MEMS), wherein the chip is a nanoelectromechanical system (NEMS), wherein the integrated circuit chip further comprises an embedded heater structure, wherein an LC circuit which comprises the SAW resonator is combined with an amplifier on the same chip, and/or wherein a local oscillator, which comprises the LC circuit herein is connected to a Pierce oscillator.

Additional preferred structures include wherein the RF-CMOS process sequence includes fabricating an array of reflector structures on both sides of the SAW device designed from shorted metal electrodes using stacked RF-CMOS layers of metal5, metal4 and the dielectric layer between them to have reflectors which are thicker than the SAW IDT to increase reflectivity and containment of the wave energy at the edges of the reflector array.

SAW resonators fabricated using CMOS technology are also contemplated as within the scope of the invention.

A heat control structure for the SAW resonator built using two CMOS process layers namely polysilicon and the ground shield is also part of the inventive subject matter and can be adopted in any of the CMOS chip devices herein. In preferred embodiments, the heat control structure is the combination of the polysilicon layer that has a TCR of 0.00049 T⁻¹, which is placed underneath the ground shield layer which acts as a heat distributing plate. The ground shield now serves dual purpose of isolation of the SAW resonator device from electromagnetic feedthrough and also for heat distribution. The polysilicon heater effectively heats up the SAW resonator structure placed directly above it.

Provided is a process for fabricating a SAW resonators using CMOS technology, comprising: designing and fabricating both SAW resonator's electrodes and the metal ground shield through a regular CMOS process sequence to obtain a SAW resonator; performing a reactive ion etch on the SAW device; performing a maskless sputtering from the front to the SAW device using ZnO, wherein the ZnO covers the entire surface including the resonator's electrodes and the exposed ground shield metal layer; patterning the SAW resonator using a mask and etching such that the ZnO will cover only the resonator area to reduce losses in the ZnO layer, wherein the non-uniform photoresist with buildup at the edges of the chip is avoided by placing the chip at the far edge of the a large circular wafer during photoresist spinning.

The process also contemplates wherein patterning the piezoelectric layer such that it covers only area above the SAW resonator to reduce propagation losses in the lossy piezoelectric layer. Acoustic propagation losses are very dominant in high frequency designs and can be addressed by the removal of piezoelectric layers in unnecessary areas. Patterning is achieved through a series of steps, resist coating, UV exposure of a designed mask and an acidic wet-etch. Resist coating uses 1.8 ┌m thick Shipley 1818 liquid photoresist which is spun on top of the CMOS die at a speed of 4000 rpm for 30 s. To avoid photoresist buildup at the edges of the CMOS die and to achieve uniform photoresist coating, the CMOS die is glued and placed on the far edge of a circular wafer during spinning. The sample is then patterned using an etch-mask which contains rectangles which covers only the resonators. Pattern development was achieved by immersing the sample in developer solution for 60 s. An etch solution that does not adversely affect the piezoelectric properties of the piezoelectric material is used. A very dilute mixture of a phosphoric acid, acetic acid and water, 1:1:80 is used for this task. Residual photoresist is removed next by immersing the die in acetone.

Another preferred embodiment of the invention includes a SAW resonator made by the processes described herein, especially those wherein signal control and processing circuitry are integrated on the same chip, and those wherein the heat control structure is the combination of polysilicon layer that has a TCR of 0.00049 T⁻¹, which is placed underneath the ground shield layer which acts as a heat distributing plate. The ground shield now serves dual purpose of isolation of the SAW resonator device from electromagnetic feedthrough and also for heat distribution. The polysilicon heater effectively heats up the SAW resonator structure placed directly above it.

SAW resonator structures which includes both the IDTs and the reflectors, increased height of the SAW resonator's reflectors to reduce diffraction losses, optimized piezoelectric regions above the resonator, optimized configurations of SAW resonators such as series-coupled or parallel-coupled SAW resonators. All these exemplary embodiments have the objective of reducing acoustic propagation losses and improving the device's quality factor. Resonators with low insertion losses and high quality factors are crucial for devices used for telecommunication purposes.

Preferred processes for fabricating a SAW device using standard CMOS technology are also contemplated, comprising the steps of: i) depositing piezoelectric material on top of SAW IDT's, and ii) performing a wet-etching of the piezoelectric material to expose the pads for bonding, wherein the SAW IDT's are patterned on the dielectic layer during CMOS fabrication and a reactive ion etch releases the IDT's from the dielectric layer before the piezoelectric material is deposited. Access to multiple metal layers in the RF-CMOS process enables construction of stacked metal layers as the reflectors, which reduce incomplete confinement of the acoustic wave energy. In the RF-CMOS process, reflectors are constructed using a combination of Metal Top, Metal 5 and the accompanying inter-metal oxides as shown in FIG. 33b.

In preferred processes, the piezoelectric material is ZnO, the wet-etching uses a very dilute acid solution, and wherein the very dilute acid solution is a two acid mixture, wherein each acid of the two acid mixture is selected from the group consisting of acetic acid, hydrochloric acid, and phosphoric acid.

Additional preferred processes include wherein the CMOS process sequence includes fabricating an absorber structure on the SAW device designed from stacking CMOS layers of metal1, metal2 and polysilicon to achieve a surface higher than the IDT level for attenuating or reflecting the acoustic waves.

SAW devices made by the processes herein are also within the scope of the invention.

A heat control structure built within the substrate silicon during the CMOS process is also part of the inventive subject matter and can be be adopted in any of the CMOS chip devices herein. In preferred embodiments, the heat control structure is an n-well layer that has a TCR of 0.5-0.75%/K, which is the highest among various CMOS process layers and wherein the n-well provides an embedded heater structure that can directly control the temperature of the substrate and the mass sensitive area without causing any disturbance on the SAW delay line path or the IDT finger design.

Provided is a process for fabricating a SAW device using CMOS technology, comprising: designing and fabricating a SAW IDT through a regular CMOS process sequence to obtain a SAW device; performing a reactive ion etch on the SAW device; performing a maskless sputtering from the front to the SAW device using ZnO, wherein the ZnO covers the entire surface including the IDT fingers and the exposed Si; etching the SAW device using a simple shadow mask, wherein the the mask is constructed using a Si, and wherein the photoresist build up covering the pad frame is completely removed by i) exposing the device after spincoating with a photoresist, applying developer, and ii) performing a second exposure and development to remove the excessive photoresist using the same exposure time and development time, and wherein the etching process is slowed using a very dilute acid solution.

The process can also include wherein the CMOS process sequence includes fabricating an absorber structure designed from stacking CMOS layers of metal1, metal2 and polysilicon to achieve a surface higher than the IDT level for attenuating or reflecting the acoustic waves.

The process also contemplates wherein etching the SAW device using a simple shadow mask comprises wherein the the mask is constructed using a square Si piece of size 2×2 mm, and wherein the photoresist build up covering the pad frame is completely removed by exposing the device for about 20 seconds after spinning a Shipley 1818 2:1 thinner for 40 sec at 5000 rpm, wherein a 2 min development in 5:1 Developer is applied, and performing a second exposure and development to remove the excessive photoresist using the same exposure time and development time, and wherein the etching process is slowed using a very dilute solution of a two acid mixture, wherein each acid of the two acid mixture is selected from the group consisting of acetic acid, hydrochloric acid, and phosphoric acid.

Another preferred embodiment of the invention includes a SAW device made by the processes described herein, especially those wherein signal control and processing circuitry are integrated on the same chip, and those wherein the n-well layer has a TCR of 0.5-0.75%/K, which is the highest among various CMOS process layers and wherein the n-well provides an embedded heater structure that can directly control the temperature of the substrate and the mass sensitive area without causing any disturbance on the SAW delay line path or the IDT finger design.

It is believed that advantages of the exemplary embodiments and/or exemplary methods of the present invention may include optimized biosensor devices, improved biosensor arrangement performance, determination of effective sensing media immobilization approaches, and SAW based biosensors that may be used to provide continuous, in-situ, and rapid detection and quantification of analytes in samples.

### BRIEF DESCRIPTION OF THE FIGURES

The patent application file contains at least one drawing executed in color. Copies of this patent or patent application publication with color drawing(s) will be provided by the Office upon request and payment of the necessary fee.

FIG. 1b is a graphic and shows the SAW resonator design parameters of a 1-port resonator.

FIG. 2(b) is a graphic and shows key design parameters and equations for a two-port resonator.

FIG. 3(b) shows an Equivalent circuit model of a two-port SAW resonator.

FIG. 4(b) is a graphic showing a cross section and a top view of a resonator.

FIG. 5(b) is a cross section of a CMOS SAW oscillator before post-processing and shows (i) a SAW Resonator IDT's and Reflectors fabricated using 0.6 um AMI CMOS Process technology. (ii) Reactive Ion Etching to remove the SiO₂. (iii) ZnO deposition using RF sputtering.

FIG. 6(a) is a graphic and shows (a) Cross-section of CMOS SAW resonator designs 1 and 2 utilizing two CMOS metal layers. The ground shield was implemented using Metal 1 and both the reflectors and transducers were implemented using Metal 2. (b) Cross-section of CMOS SAW resonator design 3 utilizing three CMOS metal layers. The ground shield was implemented using Metal 1 and both the reflectors and transducers were implemented using Metal 2. Additional acoustic wave containment was provided by an extra layer of reflectors, implemented using metal 3.

FIG. 7(a)(b)(c) is a three panel figure with graphic and two line charts and shows FEM simulation results for one-port CMOS 3.6 um resonator; (a) Meshed 3-D model of one port resonator (b) Accumulated piezoelectric Charge versus frequency (c) Displacement of versus frequency computed using Harmonic Analysis.

FIG. 8(b) shows Chip A: a SEM micrograph of 0.6 micron CMOS resonator.

FIG. 9(b) shows Chip B: CMOS Oscillator Die Photo

FIG. 10(b) is a two panel figure of scanning electron micrograph (SEM) images of 0.6 um standard CMOS samples. Left (a) Before SiO2 etch. Right (b) After RIE of SiO2. Inset: Cross-section of sample.

FIG. 11(b) is a microphotograph and graphic inset and shows Resonator's interdigital transducers and reflectors after reactive-ion-etch. Inset: Cross-section of etched interdigital fingers. (a) is an SEM image of cleaved Si—ZnO sample. Illustrates the c-axis crystal growth orientation perpendicular to the substrate. (b) SEM image of thick (2.4 um) ZnO on 0.6 urn CMOS die.

FIG. 12(b) is two panel figure showing a Topography Profile line graph (top) and a microphotograph of grain size measurement using AFM for the 0.6 um CMOS SAW resonator chip.

FIG. 13(b) is a multi-panel figure showing surface roughness AFM measurements of 0.6 um CMOS SAW resonator chip. Measured average roughness was 17.7 nm.

FIG. 14(b) is a graph and shows X-Ray Diffraction 2θι-scan of CMOS resonator chip. Height of ZnO (002) is 2.9 cps.

FIG. 15(b) is a two panel figure showing a graphic (a) left of placement of die on far edge of wafer during photoresist spinning. Right (b) Etch mask containing squares which cover the resonators.

FIG. 16(b) is a two panel photomicrograph showing (Left) Microscope image of unetched 0.6 um CMOS SAW resonator with photoresist pattern on top of resonator. (Right) Etched ZnO sample after immersion in acid solution.

FIG. 17(b) Experimental Setup: clockwise from left: Bonded Die. Middle: Device under test (DUT) in DIP 40 package. Bottom: DUT connected to HP8712 network analyzer.

FIG. 17(b) (2) is a SEM and microscope image along with a graphic and shows SEM and microscope image of CMOS SAW resonator 2. (a) Etched edge of ZnO. (b) Resonator 2 after ZnO etching. (c) Acid wet-etch process where resonator is masked using photoresist.

FIG. 18(b) shows the Measured and Simulated S21 Transmission Characteristics of 1-port Resonator.

FIG. 19(b) is a schematic of a 2-port SAW Resonator connected as a Pierce Oscillator.

FIG. 20(b) shows the Phase noise and steady-state analysis of SAW Oscillator.

FIG. 21(b) is a microscope image and shows a whole chip fabricated using 0.6 um CMOS process technology. It consist of three 2-port resonators and Thru calibration structure.

FIG. 22(b) is a graphic (a) and (b) a photo showing the experimental setup of the device with probes connected.

FIG. 23(b) is a set of three line graphs and shows Magnitude and Phase S21 measurement results of three 0.6 um CMOS resonators.

FIG. 24(b) is a set of three circular graphs and shows S₁₁ measurement results of three 0.6 um CMOS resonators.

FIG. 25(b) is a set of three line graphs and shows Impedance measurements results of three 0.6 um CMOS resonators.

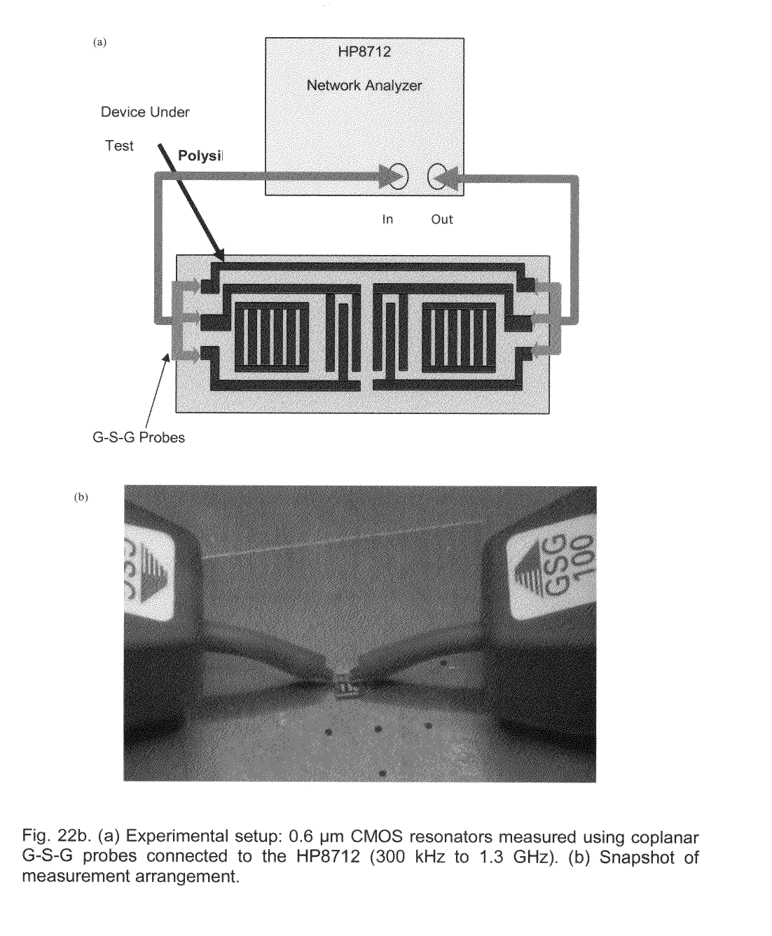

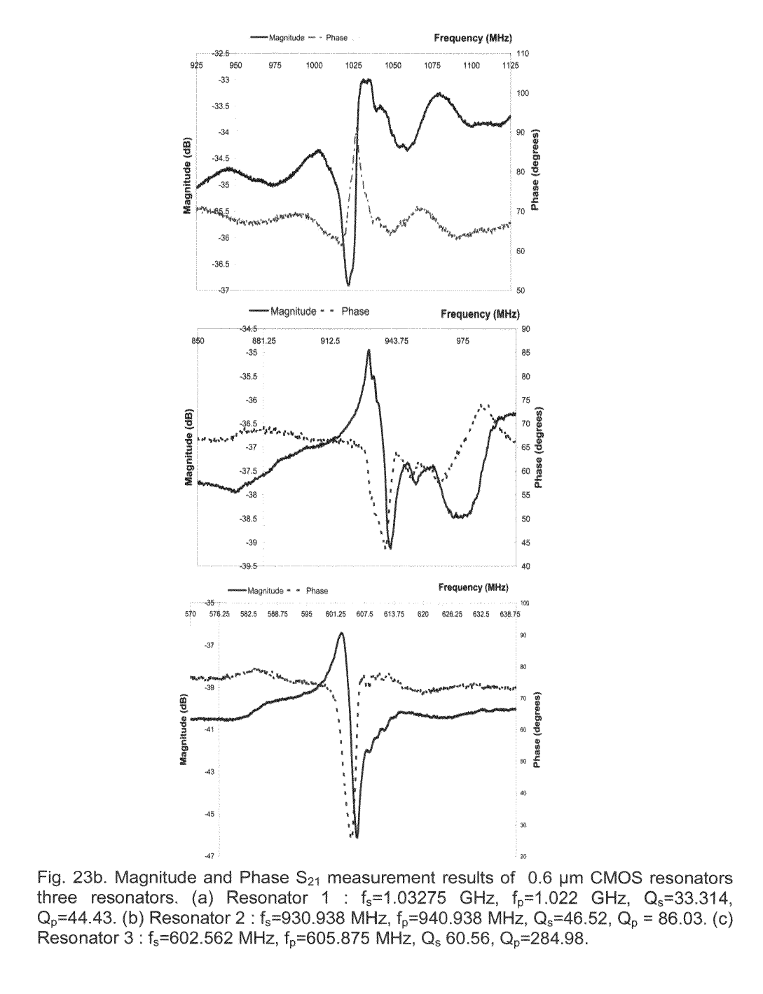

FIG. 23(b)(2) is a line graph and shows the comparison between the design, measured, and extracted S21 Magnitude Transmission characteristics of Resonator 1. Design and extracted characteristics were simulated using the equivalent circuit model shown in FIG. 4b. Measured graph obtained measurements using the experimental setup shown in FIG. 22b.

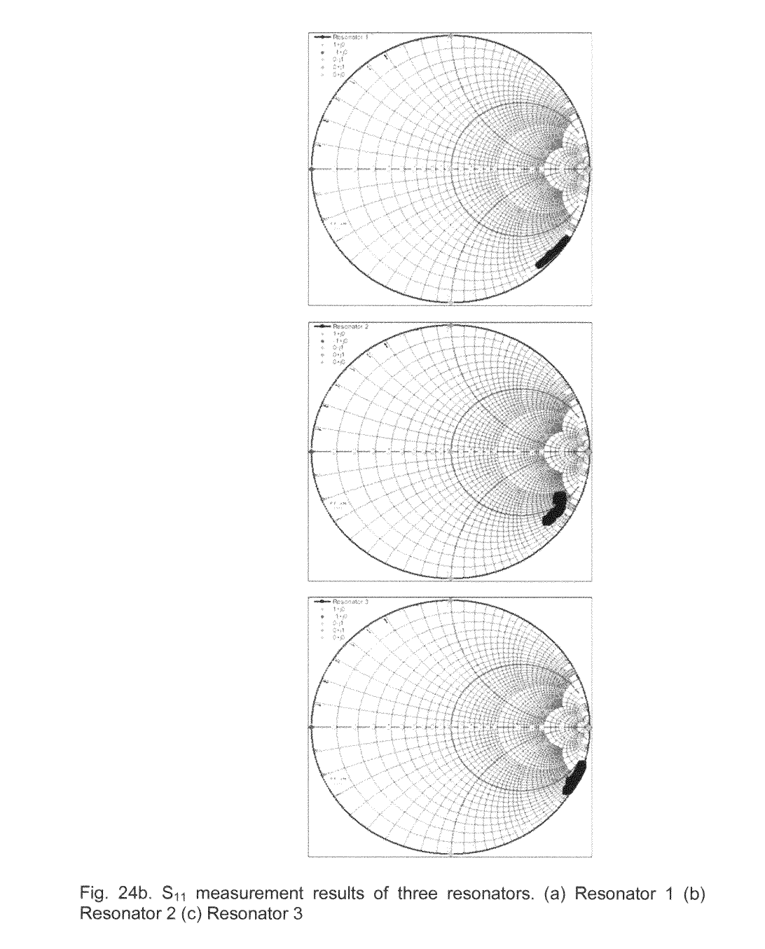

FIG. 24(b)(2) is a line graph and shows the comparison between the design, measured, and extracted S21 Magnitude Transmission characteristics of Resonator 2. Design and extracted characteristics were simulated using the equivalent circuit model shown in FIG. 4b. Measured graph obtained measurements using the experimental setup shown in FIG. 22b.

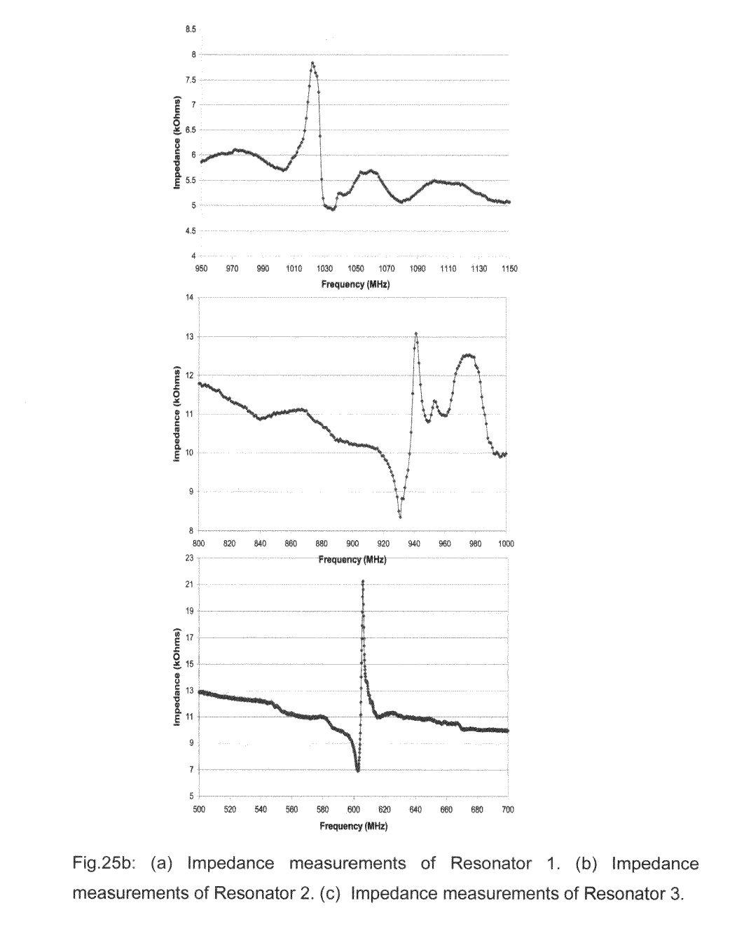

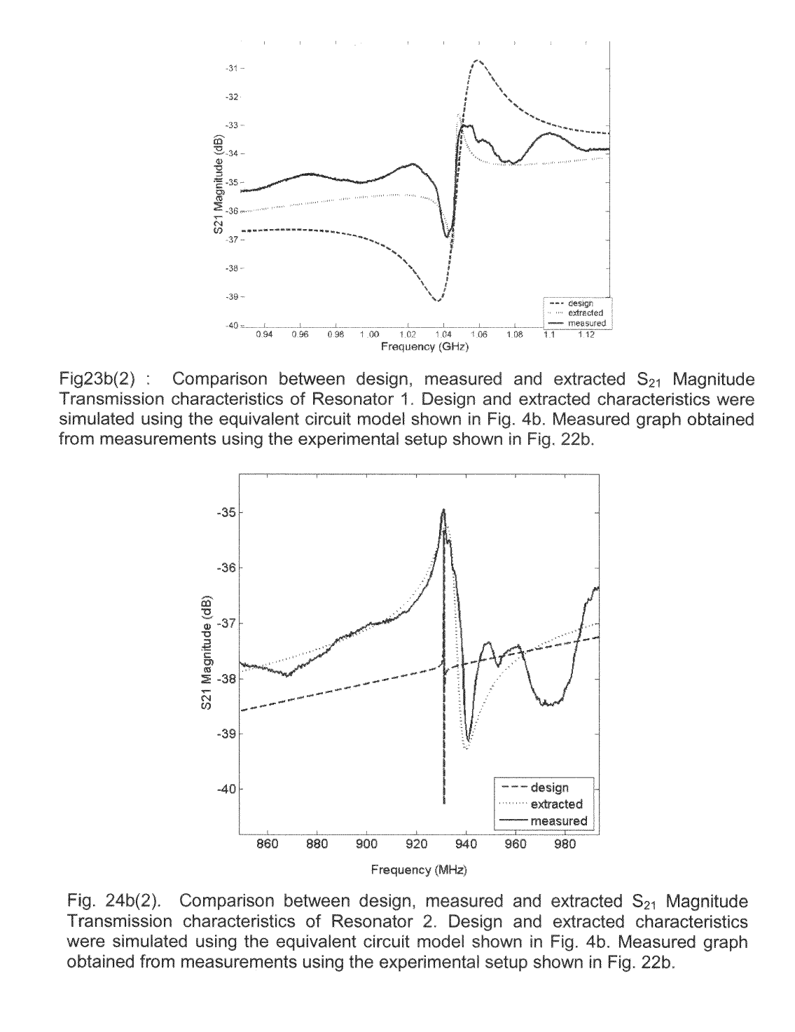

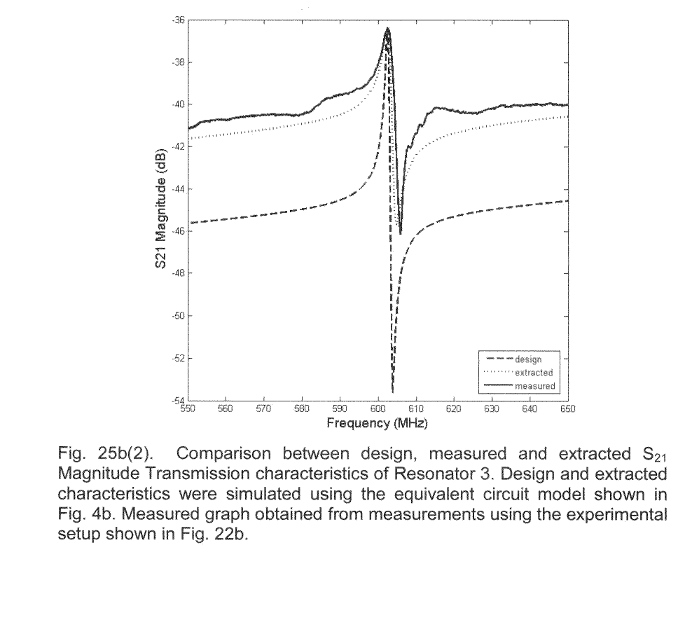

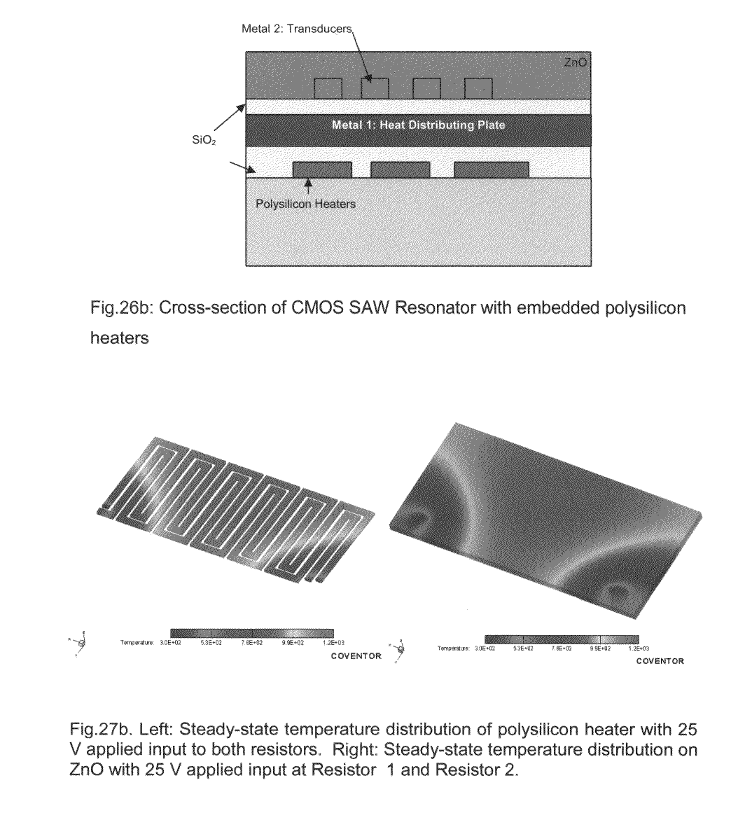

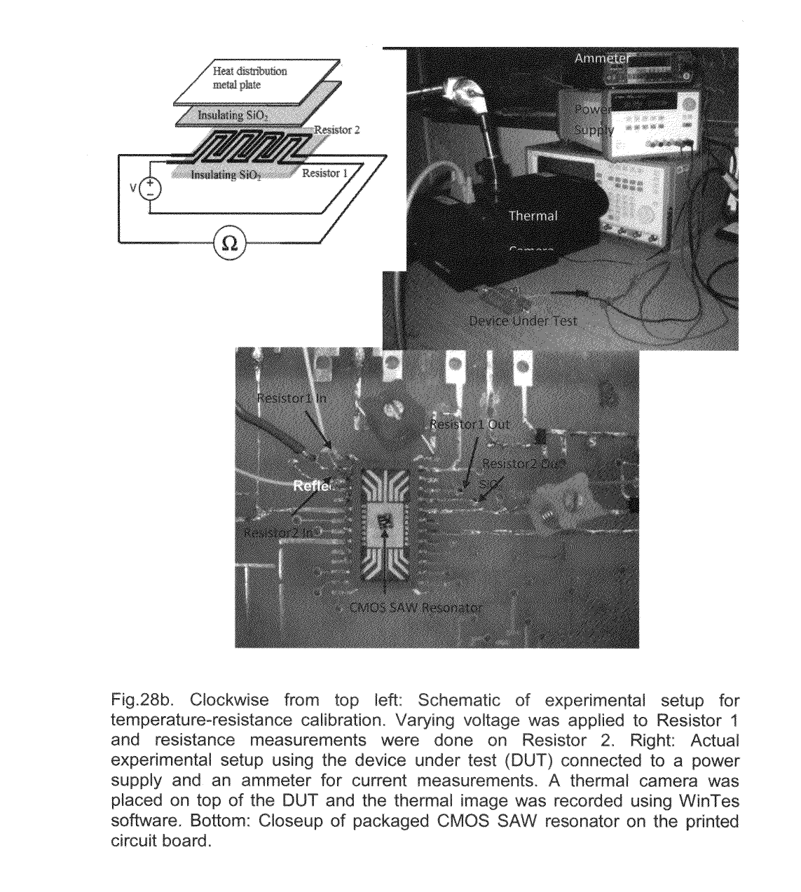

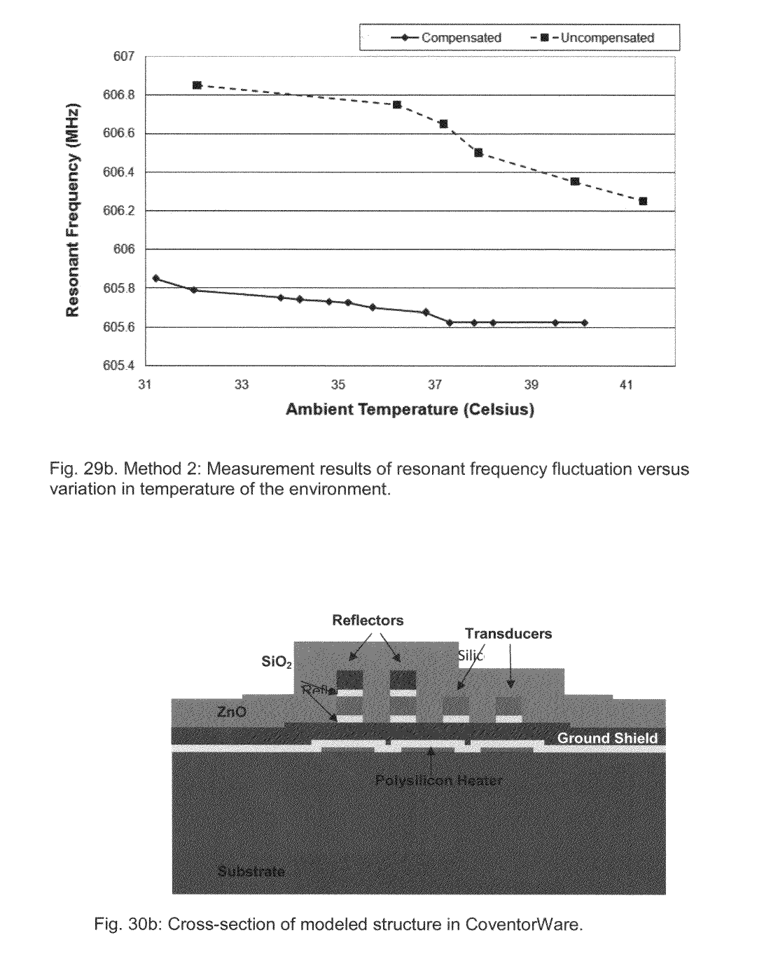

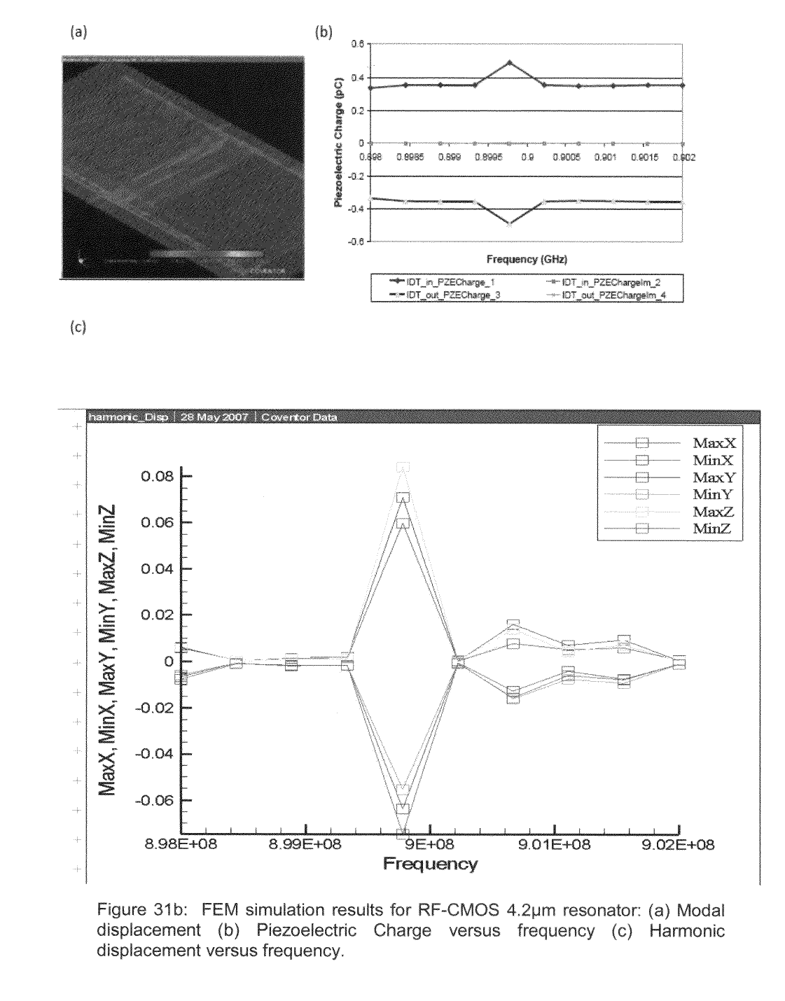

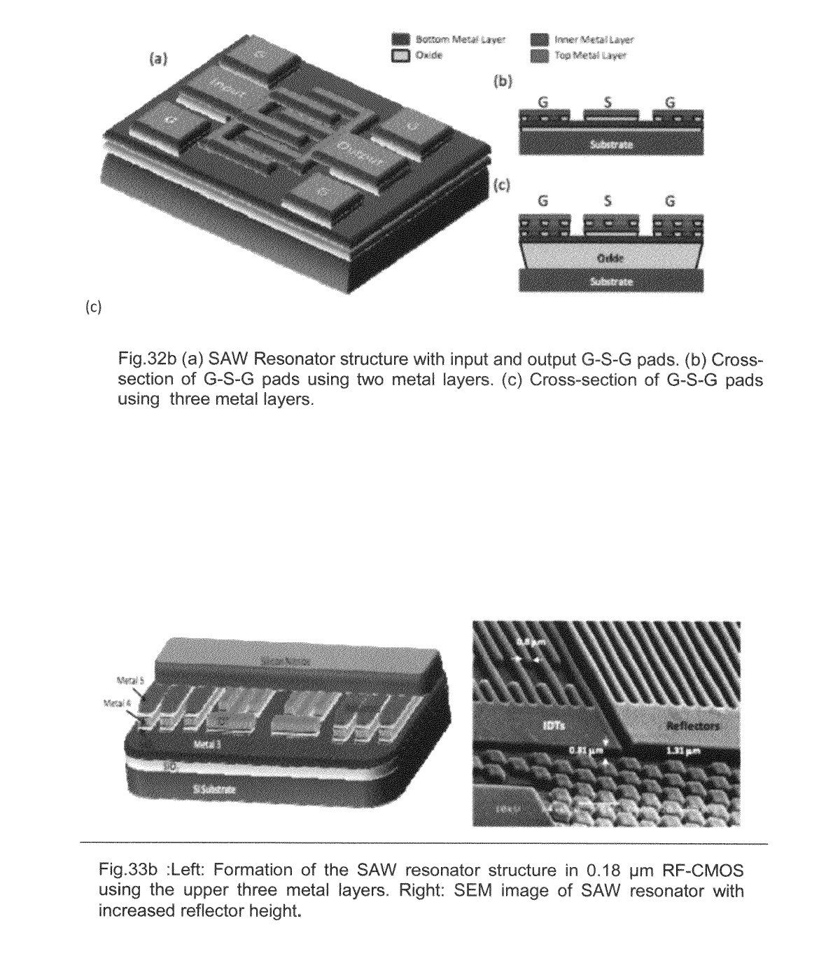

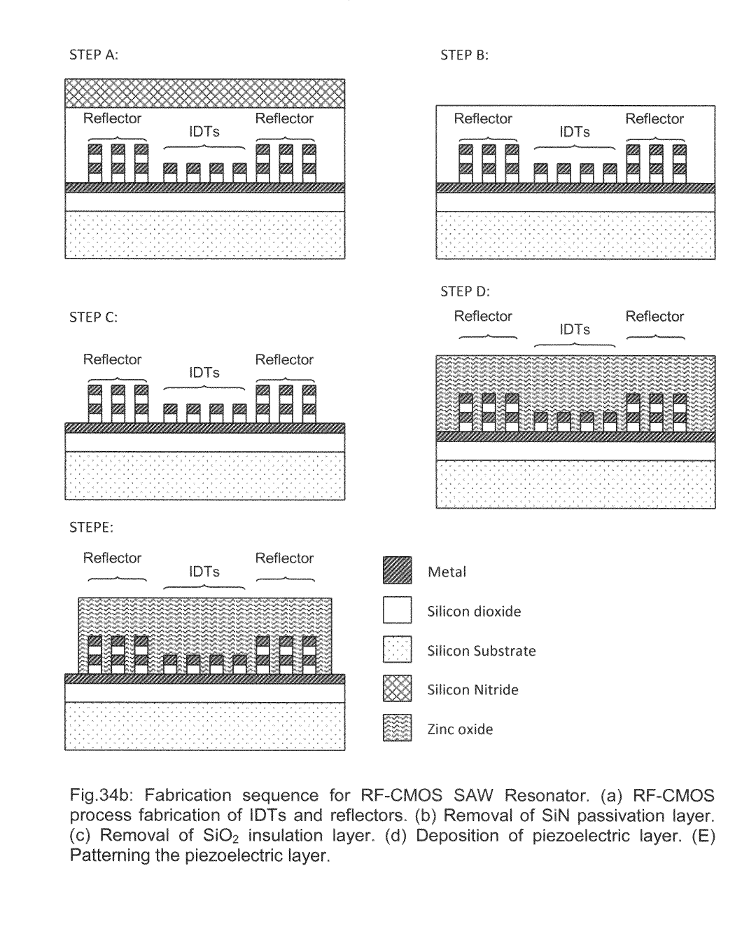

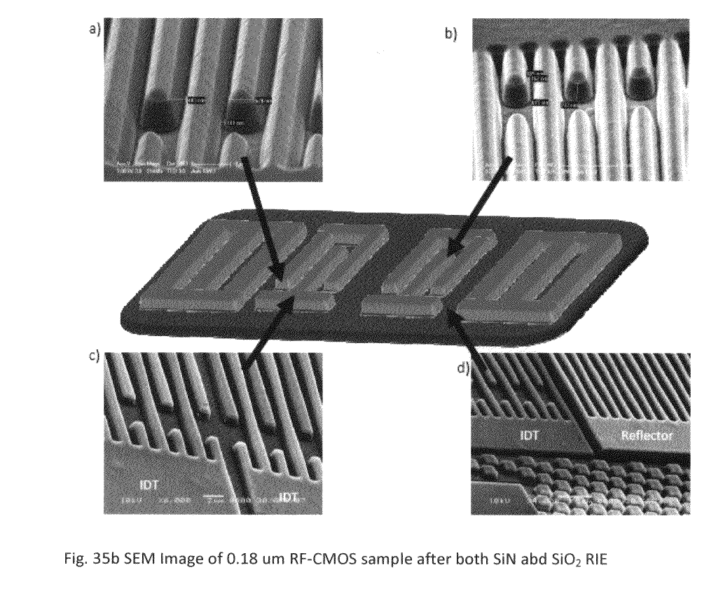

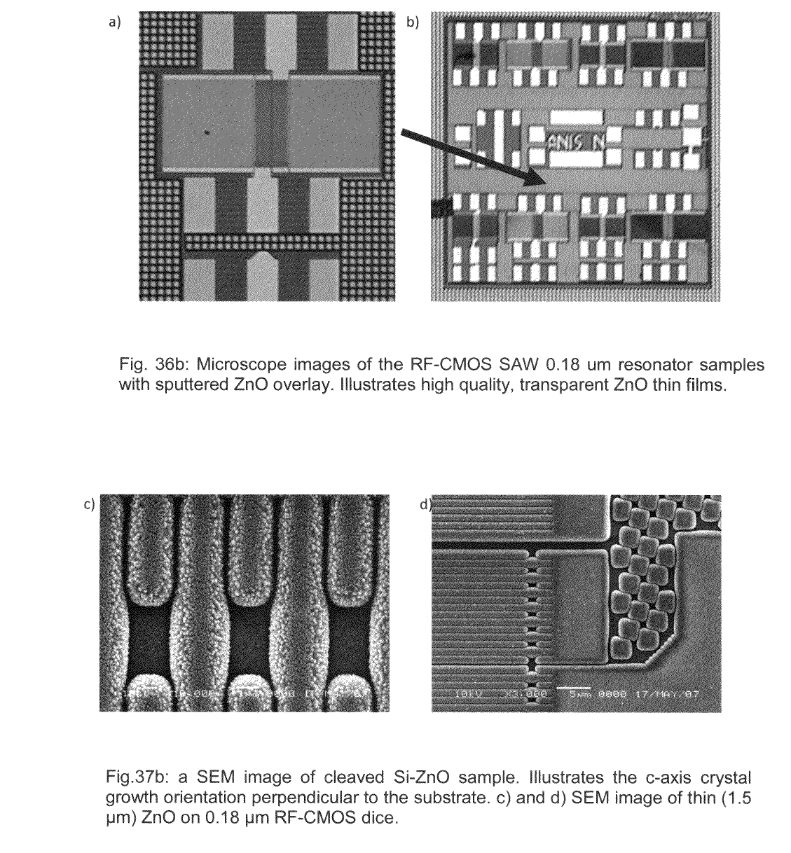

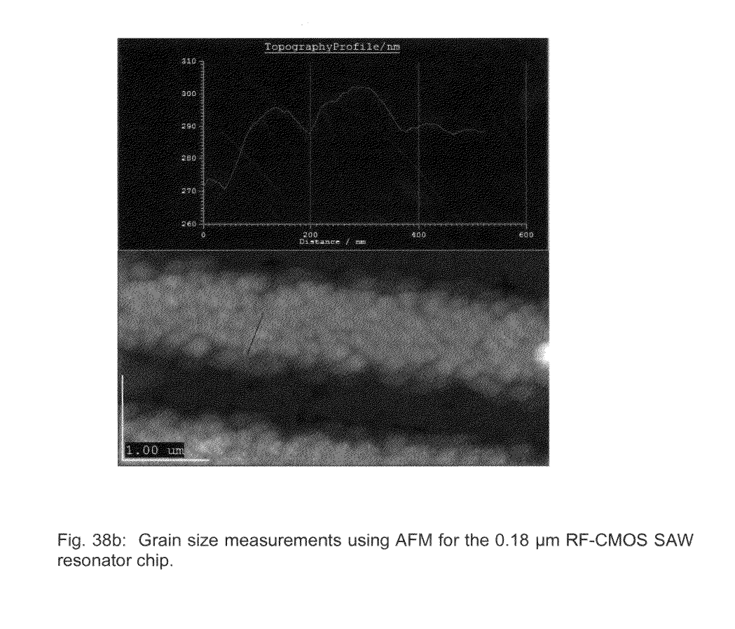

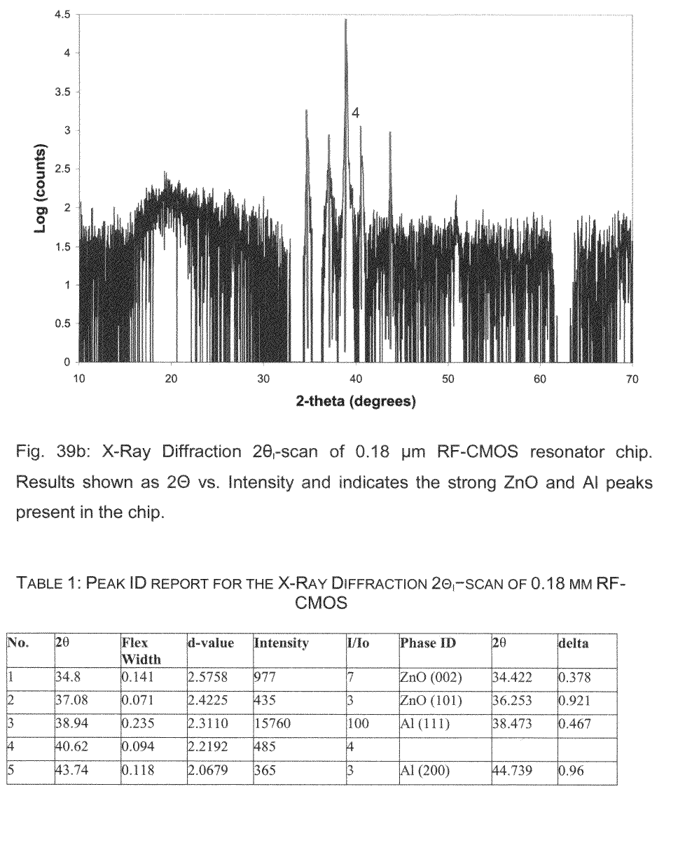

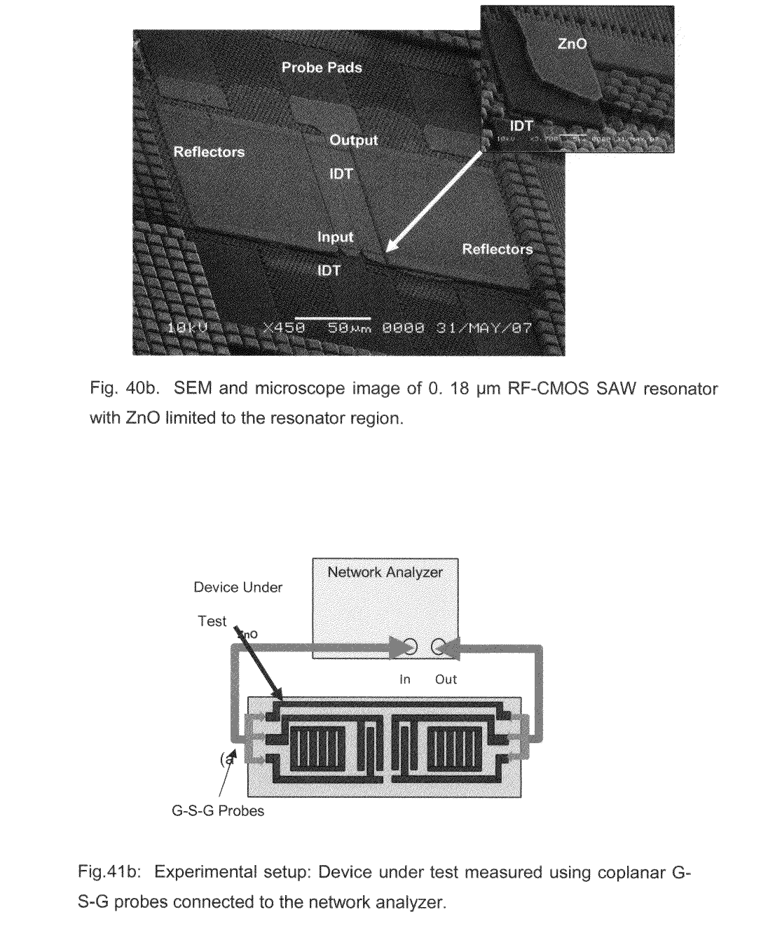

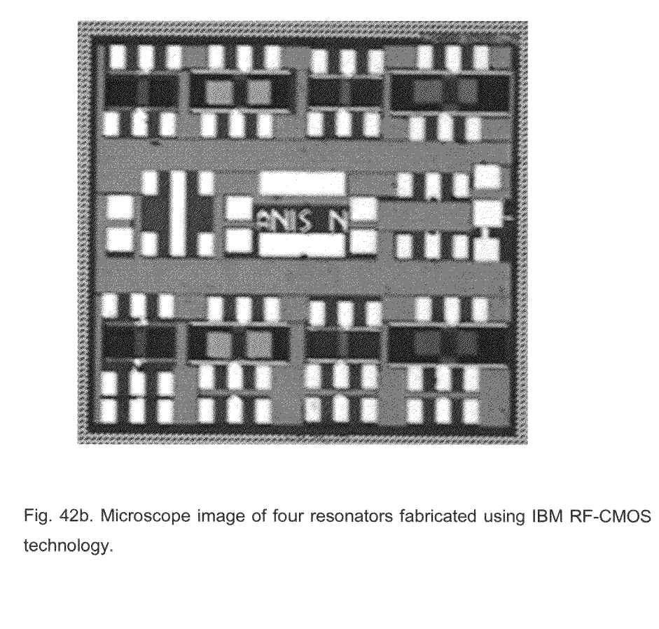

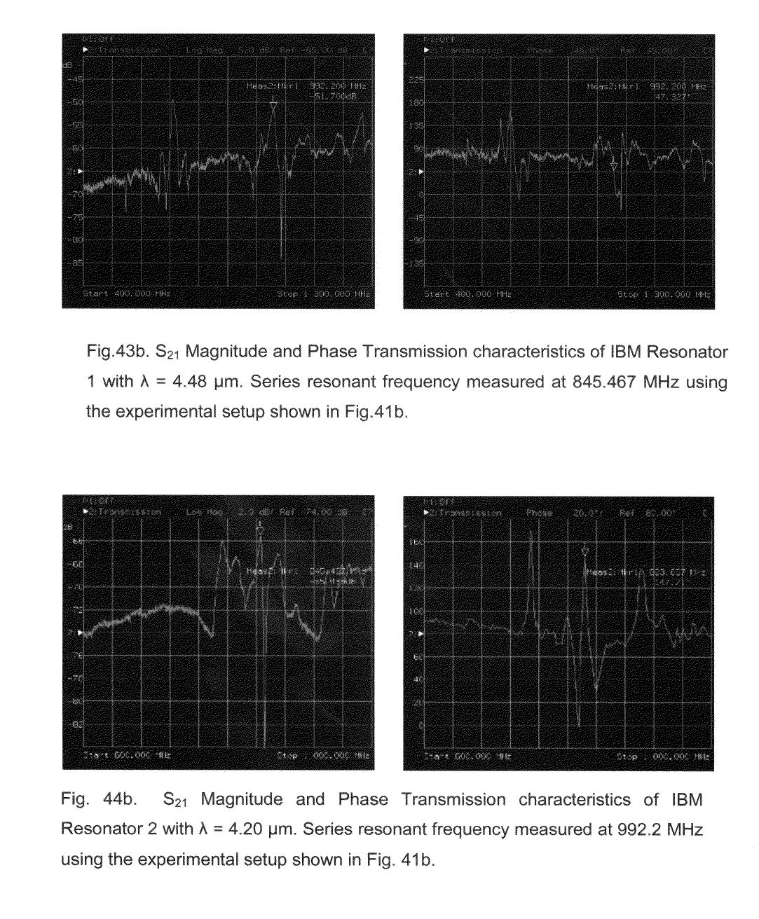

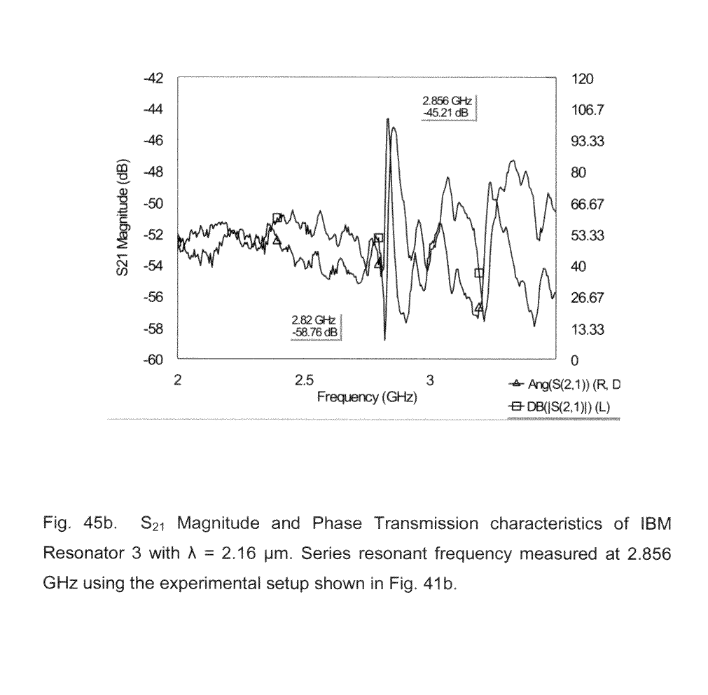

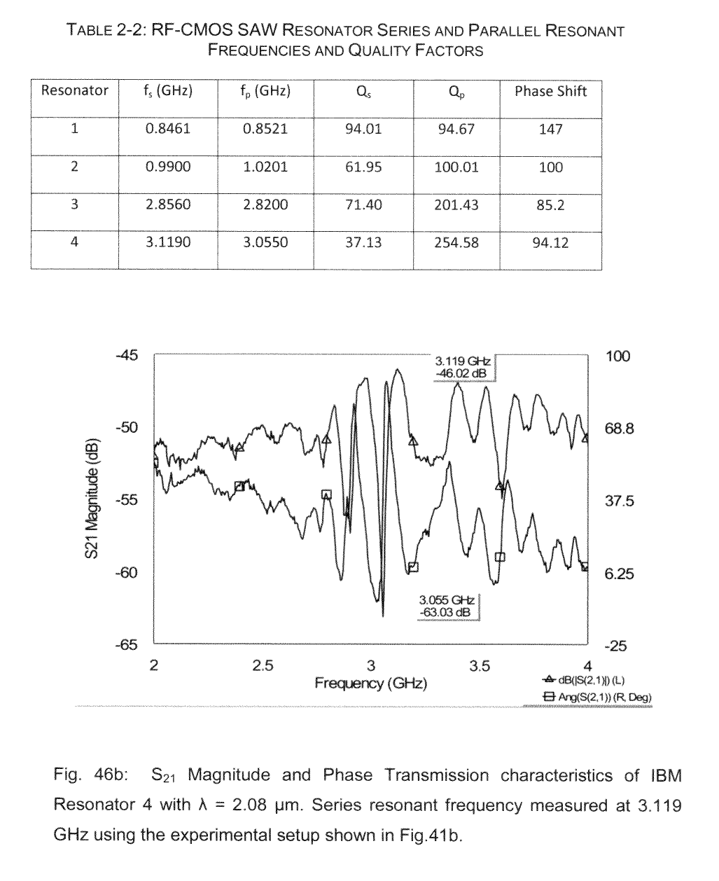

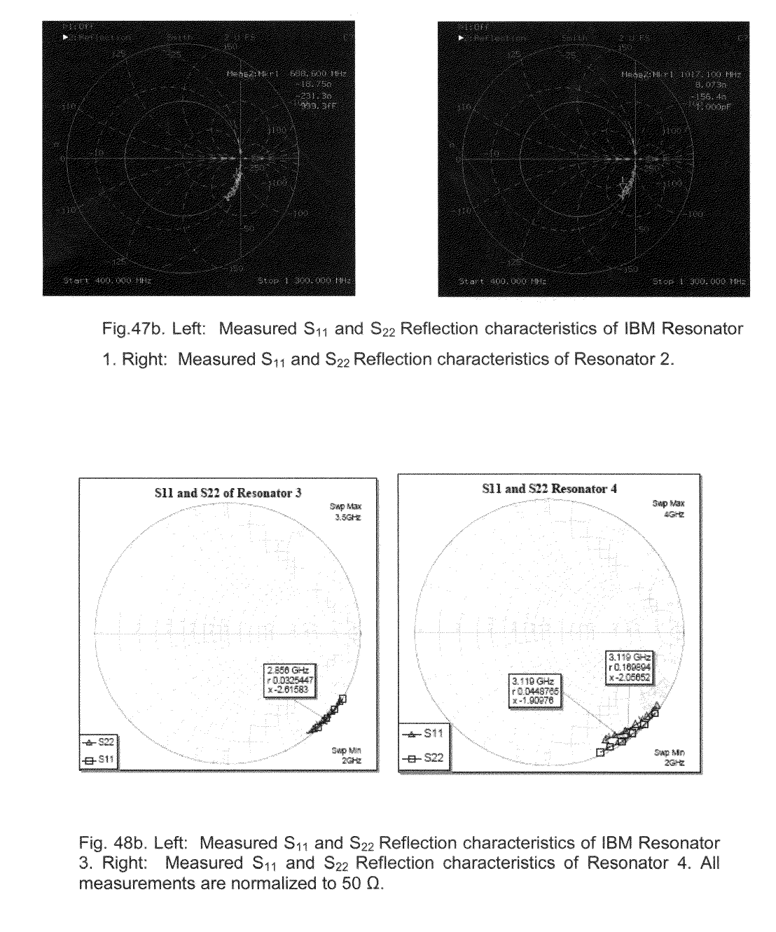

FIG. 25(b)(2) is a line graph and shows the comparison between the design, measured, and extracted S21 Magnitude Transmission characteristics of Resonator 3. Design and extracted characteristics were simulated using the equivalent circuit model shown in FIG. 4b. Measured graph obtained measurements using the experimental setup shown in FIG. 22b.

FIG. 26(b) is a graphic and shows a cross-section of CMOS SAW Resonator with embedded polysilicon heaters.

FIG. 27(b) is a graphic and shows (Left) the steady state temperature distribution of polysilicon heater with 25 V applied input to both resistors. (Right) Steady state temperature distribution on ZnO with 25 V applied input at Resistor 1 and Resistor 2.

FIG. 28(b) is a three panel figure with a schematic and two photographs showing a schematic of the experimental setup for temperature resistance calibration. Varying voltage was applied to Resistor I and resistance measurements were done on Resistor 2. (Right) Actual experimental setup using the device under test (DUT) connected to a power supply and ampmeter for current measurements. A thermal camera was placed on top of the DUT and the thermal image was recorded using WinTes software. (Bottom) Closeup of packaged CMOS SAW resonator on the printed circuit board.

FIG. 29(b) is a line graph and shows measurement results of resonant frequency fluctuation versus variation in temperature of the environment.

FIG. 30(b) is a graphic and shows a cross-section of modeled structure in CoventorWare.

FIG. 31(b) is a three panel figure and shows (a) a graphic of FEM simulation results for RF-CMOS 4.2 um resonator, modal displacement. (b) Piezoelectric Charge vs. frequency (c) Harmonic displacement versus frequency.

FIG. 32(b) is a three panel graphic and shows (a) a SAW Resonator structure with input and output G-S-G pads (b) Cross-section of G-S-G pads using two metal layers (c) Cross-section of G-S-G pads using three metal layers.

FIG. 33(b) is a two panel figure with a graphic and photomicrograph and shows Left: Formation of the SAW resonator structure in 0.18 μm RF-CMOS using the upper three metal layers. Right: SEM image of SAW resonator with increased reflector height.

FIG. 34(b) is a five panel figure showing Steps A-E and shows Fabrication sequence for RF-CMOS SAW Resonator. (a) RF-CMOS process fabrication of IDTs and reflectors. (b) Removal of SiN passivation layer. (c) Removal of SiO₂ insulation layer. (d) Deposition of piezoelectric layer. (E) Patterning the piezoelectric layer.

FIG. 35(b) is a combined graphic with four SEM images and shows SEM image of 0.18 μm RF-CMOS sample after both SiN and SiO₂ RIE.

FIG. 36(b) is a two-panel figure and shows Microscope images of the RF-CMOS SAW 0.18 um resonator samples with sputtered ZnO overlay. Illustrates high quality, transparent ZnO thin films.

FIG. 37(b) is a two-panel figure and shows a SEM image of cleaved Si—ZnO sample. Illustrates the c-axis crystal growth orientation perpendicular to the substrate. c) and d) SEM image of thin (1.5 μm) ZnO on 0.18 μm RF-CMOS dice.

FIG. 38(b) is a two part figure and shows topography profile (top) and grain size (bottom). Grain size measurements using AFM for the 0.18 μm RF-CMOS SAW resonator chip.

FIG. 39(b) is a bar chart and shows an X-ray diffraction 2-theta scan of 0.18 um RF-CMOS resonator chip. Results shown as 2 theta vs. Intensity and indicates the strong ZnO and Al peaks present in the chip.

FIG. 40(b) is a photomicrograph with inset and shows SEM and microscope image of 0.18 μm RF-CMOS SAW resonator with ZnO limited to the resonator region.

FIG. 41(b) is a graphic and shows Experimental setup: Device under test measured using coplanar G-S-G probes connected to the network analyzer.

FIG. 42(b) is a photomicrograph and shows Microscope image of four resonators fabricated using IBM RF-CMOS technology.

FIG. 43(b) is a two-panel line graph and shows S₂₁ Magnitude and Phase Transmission characteristics of IBM Resonator 1 with λ=4.48 μm. Series resonant frequency measured at 845.467 MHz using the experimental setup shown in FIG. 41b.

FIG. 44(b) is a two panel line graph and shows S₂₁ Magnitude and Phase Transmission characteristics of IBM Resonator 2 with └=4.20 ┌m. Series resonant frequency measured at 992.2 MHz using the experimental setup shown in FIG. 41b.

FIG. 45(b) is a line graph and shows S₂₁ Magnitude and Phase Transmission characteristics of IBM Resonator 3 with λ=2.16 μm. Series resonant frequency measured at 2.856 GHz using the experimental setup shown in FIG. 41b.

FIG. 46(b) is a line graph and shows S₂₁ Magnitude and Phase Transmission characteristics of IBM Resonator 4 with λ=2.08 μm. Series resonant frequency measured at 3.119 GHz using the experimental setup shown in FIG. 41b.

FIG. 47(b) is a two panel set of reflection characteristics graphs and shows Left: Measured S₁₁ and S₂₂ Reflection characteristics of IBM Resonator 1. Right: Measured S₁₁ and S₂₂ Reflection characteristics of Resonator 2.

FIG. 48(b) is a two panel set of reflection characteristics graphs and shows Left: Measured S₁₁ and S₂₂ Reflection characteristics of IBM Resonator 3. Right: Measured S₁₁ and S₂₂ Reflection characteristics of Resonator 4. All measurements are normalized to 50Ω.

Table 2-2 compares 4 resonators and shows RF-CMOS SAW resonator series and parallel resonant frequencies and quality factors.

### DETAILED DESCRIPTION OF THE PREFERRED EMBODIMENTS

CMOS is short for complementary metal oxide semiconductor. Pronounced see-moss, CMOS is a widely used type of semiconductor. CMOS semiconductors use both NMOS (negative polarity) and PMOS (positive polarity) circuits. Since only one of the circuit types is on at any given time, CMOS chips require less power than chips using just one type of transistor. This makes them particularly attractive for use in battery-powered devices, such as portable computers. Personal computers also contain a small amount of battery-powered CMOS memory to hold the date, time, and system setup parameters.

SAW (surface acoustic wave) devices are widely used as electronic filters, delay lines, resonators in today's communication systems. Although telecommunication industry is the largest user of these devices, SAW based sensors have many attractive features to be explored for emerging technologies in automotive (torque, pressure), medical (biosensor) and commercial (vapor, gas, humidity) applications.

Surface acoustic waves (both Rayleigh and pseudo-SAW) are generated at the free surface of a piezoelectric material. An application of a varying voltage to the metal IDT (interdigital transducer) generates the acoustic wave on the input side. In the basic configuration there is an input IDT and an output IDT. The acoustic wave generated by the input IDT travels through the region called the delay line and reaches the output IDT where the mechanical displacements due to the acoustic waves create a voltage difference between the output IDT fingers. One of the most widely used and interesting sensing mechanism that acoustic wave sensors employ is mass loading. Prominent applications are in film thickness monitoring, gas, liquid phase chemical sensing and biosensing. The delay lines of SAW devices are coated with some bio/chemical coating which selectively reacts with the entity under analysis. This interaction produces a shift in the resonant frequency of the SAW device. By measuring this shift in frequency domain, a detailed analysis of the entity being sensed can be completed. FIG. 24 depicts the basic principle of SAW based bio/chemical sensors employing the mass loading scheme.

Using a combination of IC compatible technologies, such as Si micromachining, thin film deposition, bio/chemical layer growth, integrated electronics, smart structures and systems can be realized. Considering the advantages that CMOS technology provides along with the ever-developing CMOS compatible MEMS processes, the SAW technology performance can be improved significantly. Therefore, an array of SAW delay lines were designed and fabricated through a regular CMOS process sequence, characterized and post-processed using widely used MEMS techniques.

The present invention provides a GHz surface acoustic wave (SAW) resonator that is compatible with commercial RF-CMOS technology. The usage of mainstream RF-CMOS technology process to fabricate submicron width interdigital transducers (IDTs) and reflectors allow the RF-CMOS SAW resonator to achieve GHz frequencies using an inexpensive, robust process sequence. Apart from novelties of integrating the device in RF-CMOS process, the device also has novelties in terms of its structure. Due to the submicron width of the electrodes, the RF-CMOS SAW is miniature, with dimensions measuring (150 μm×300 μm). The RF-CMOS SAW resonator is equipped with isolation from electromagnetic feed-through by placing a single, integrated metal shield underneath the transducers and reflectors. Access to multiple metal layers in the RF-CMOS process enables construction of stacked metal layers as the reflectors, which reduce incomplete confinement of the acoustic wave energy. Fabricated RF-CMOS SAW resonators have demonstrated resonant frequencies up to 3.12 GHz and quality factors of 285. Measurement comparison between single layer reflectors and stacked reflectors has indicated 200% improvement in the quality factor of the device.

The novelty of the device can be divided into two major categories: fabrication method and device structure. Traditionally, RF-SAW resonators were manufactured using full-custom fabrication steps, requiring costly fabrication methods such as e-beam lithography. Novel, creative techniques of integrating the RF SAW resonators using a commercial RF-CMOS process provides an inexpensive method of fabricating submicron (<1 μm) electrodes for the purpose of generating RF frequency resonators. The resonator structures were fabricated using state-of-the-art, RF-CMOS 0.18 μm process, and the minimum designed electrode width was 0.52 μm, capable of generating 3.12 GHz resonant frequency. To enable compatibility with the RF-CMOS process, the piezoelectric layer was placed on top of the resonator structures as a post-RF-CMOS process. This RF-CMOS technology has capabilities of constructing resonators with resonant frequencies up to 5.9 GHz.

The method of fabricating the RF-CMOS SAW resonator comprises of the following steps:
STEP A: Utilizing mainstream RF-CMOS process to fabricate the interdigital transducers and reflectors.
STEP B: Removing the top SiN passivation layer.
STEP C: Removing the insulating silicon dioxide layer.
STEP D: Depositing a thin piezoelectric layer on top of the entire chip.
STEP E: Patterning the piezoelectric layer to be only on top of the RF resonator.
   i. The piezoelectric layer comprises of zinc-oxide (ZnO) having a thickness that is a function of a desired resonant frequency of the SAW resonator.
   ii. STEP E is performed by the steps of:
      STEP 1: Spinning photoresist onto the piezoelectric layer.
      STEP 2: Etching the piezoelectric layer using a chemical that is not harmful to the metal electrodes.

The RF-CMOS SAW resonator has several features which were designed to improve the performance of the resonator. The first feature of the device aims to counteract diffraction loss due to incomplete confinement of the wave energy at the edges of the reflector array using stacked reflectors. Different variations of reflector structures such as ridge reflectors, deep and shallow etched grooves have been reported to increase the reflectivity (r) of these reflectors. The availability of a large number of high resolution metal layers, allows the formation of stacked reflectors. The stacked reflectors provide both increase in reflector height as well as creation of grooves in the piezoelectric layer. Grooves in the piezoelectric layer were formed due to the placement of the resonator structure underneath the piezoelectric layer. Comparative measurements between single layer and double layer reflectors have shown up to 200% increase in quality factor of the device.

SAW devices fabricated on top of conducting silicon substrates are highly susceptible to electromagnetic feed-through. The next novel feature of the RF-CMOS SAW resonator thwarts this effect by inserting a ground shield layer underneath the entire device to isolate it from undesired coupling through the Si substrate. With proper connections, this ground shield can also be used to provide a well-established ground reference plane. The common electrical ground plane was attained by positioning two ground metal pads, with adequate via connections to the ground plane. The availability of multiple metal layers in current CMOS processes enables the designer to assemble a SAW device structure with separate metal layers for its IDTs and ground shield. The IDTs were constructed using the inner metal layer. To provide planarity of the device and taking into account that the reflectors were fabricated using the top metal layer, the G-S-G pads were fabricated using the top metal layer.

### II. Design

The mass sensitivities of different acoustic devices are related to structure geometry, resonant center frequency, and electromechanical coupling. In order to explore all of these design parameters, an array of SAW devices were designed. In one embodiment, the important dimensions of the devices that were fabricated include four devices on the dies and were tested with finger width of 2.40 μm, finger spacing of 2.40 μm and a period of 9.60 μm. The apertures were picked to be 54.80 μm (device 1 and 2), 502.80 μm and 244.80 μm. 24 and 32 finger pairs were used with delay line lengths of 288 μm and 384 μm. Note that all of these devices were designed on the same die which is a 2.2 mm by 2.2 mm tiny chip. The design was fabricated in AMI 1.5 μm 2 metal, 2 poly process through MOSIS. In order to comply with the design rules for this technology, the minimum finger spacing for the IDTs is limited to 2.4 μm. This limitation is due to the minimum metal to metal spacing for the aforementioned technology.

The most important specification for SAW device design is the center frequency, which is determined by the period of the IDT fingers and the acoustic velocity of the piezoelectric material.

The governing equation that determines the operation frequency is

v SAW=λ×fc
λ: the wavelength at fc, determined by the periodicity of the IDT.
fc: the center frequency of the device
vSAW: the velocity of the SAW

For the case of devices that were tested

λ=p=finger width×4=2.4 μm×4=9.6 μm

Based on tabulated data and calculations for the corresponding design dimensions vSAW for ZnO is 3820 m/s. This translates into a center frequency of fc=3820 m/s/9.6 μm=397.916 MHz.

### III. Saw Fabrication Sequence and Results

The conventional SAW devices are typically built by depositing a piezoelectric material (quartz, lithium tantalite, lithium niobate, zinc oxide) on a substrate and patterning the IDTs on top of the piezoelectric film. This sequence of fabrication does not comply with any commercially available CMOS process as it requires an extra step to deposit the piezoelectric material. It has been reported that enhanced electromechanical coupling is theoretically possible using piezoelectric films overlaying interdigital metal electrodes. Therefore, IDT under the piezoelectric material idea is employed for this work. By depositing the piezoelectric material on top of the IDTs as a post processing step, the CMOS process is not disturbed.

For device stability as a function of temperature it is essential that the temperature coefficient of delay (TCD) be as small as possible. The slope of the TCD as a function of temperature for SAW substrates is mainly negative, so that an increase in temperature will cause a downward shift in IDT center frequency and vice-versa. Due to this strong temperature dependence of the device performance and for precise control of the temperature to study the effects of temperature on the mass sensitive layer and the analyte of interest, a novel heater design is developed. For the heater elements n-well was picked as the resistive layer. The n-well layer has a TCR of 0.5-0.75%/K, which is the highest among various CMOS process layers. Moreover, n-well provides an embedded heater structure that can directly control the temperature of the substrate and the mass sensitive area without causing any disturbance on the SAW delay line path or the IDT finger design as in the case of other candidate layers (e.g. polysilicon, metal) for resistive heating.

The major distortions in the transfer characteristics of SAW devices occur due to interference of the reflected waves and the triple transit effect. In Rayleigh wave devices, acoustic absorbers were shown to be effective against the reflections. They consist of soft materials located on the surface, at the edges of the device. In order to investigate the performance of the SiO2 in reflecting or attenuating acoustic waves, an absorber structure was designed from stacking CMOS layers of metal 1, metal2 and polysilicon. By stacking these dummy strips, a surface higher than the IDT level was created which is investigated for attenuating or reflecting the acoustic waves.

A. Step 1: Removal of Oxides

After the chips are fabricated, they are covered with the overglass protection and the dielectrics (SiO2) over and underneath the metal and poly layers. The first step in the fabrication is RIE (Reactive Ion Etch). This step has been developed, examined, and characterized previously. Note that AMI 1.5 μm process contains only two metal layers, one of which is already being used as IDTs in this run and the second metal layer will be used in the absorber structures for two main purposes. 1) To increase the height of the absorber compared to the height of the IDTs 2) To act as a mask layer that protects the oxide, which is built up under this layer. The RIE etches the dielectric that is not covered with aluminum, including field oxide, overglass, and intermetal dielectrics. The dies that were fabricated through MOSIS were RIE etched through MEMS-Exchange. The etching was carried out in a Plasma Therm 72 RIE equipment under 40 mTorr pressure.

The etch rate is 250 Å/min. The depth of the total oxide removed by the etch process is 1.5 μm. After the RIE step is completed, three major areas are defined on the surface. The absorbers, the IDTS (both of which are expected to retain their dielectric layers underneath) and exposed Si, which lay between the IDTs and the area that will define the delay line.

B. Step 2: Sputtering of ZnO

ZnO finds wide applications in SAW devices due to its strong piezoelectric effect among non ferroelectric materials. A variety of deposition techniques were used for the growth of ZnO on various substrates. Among them sputtering is considered to be the most favorable one as it is possible to obtain well oriented and uniform ZnO films. Therefore, RF magnetron sputtering was the choice of deposition in our work.

By maskless sputtering from the front, the ZnO covers the entire surface including the IDT fingers and the exposed Si. This inevitably creates bulks of ZnO layers between the IDT fingers. Sputter deposition of zinc oxide shows superior properties over other deposition methods, but the quality of the sputtered film and the growth constitutes a major interest in SAW related applications. The ZnO was deposited on the previously etched dies through MEMS-Exchange. The targeted thickness was 3.0 μm and the measured film thickness variation was (±%) 13.1. Argon and oxygen were used with a set-up time of 180 min in an MRC Sputter at 200° C.

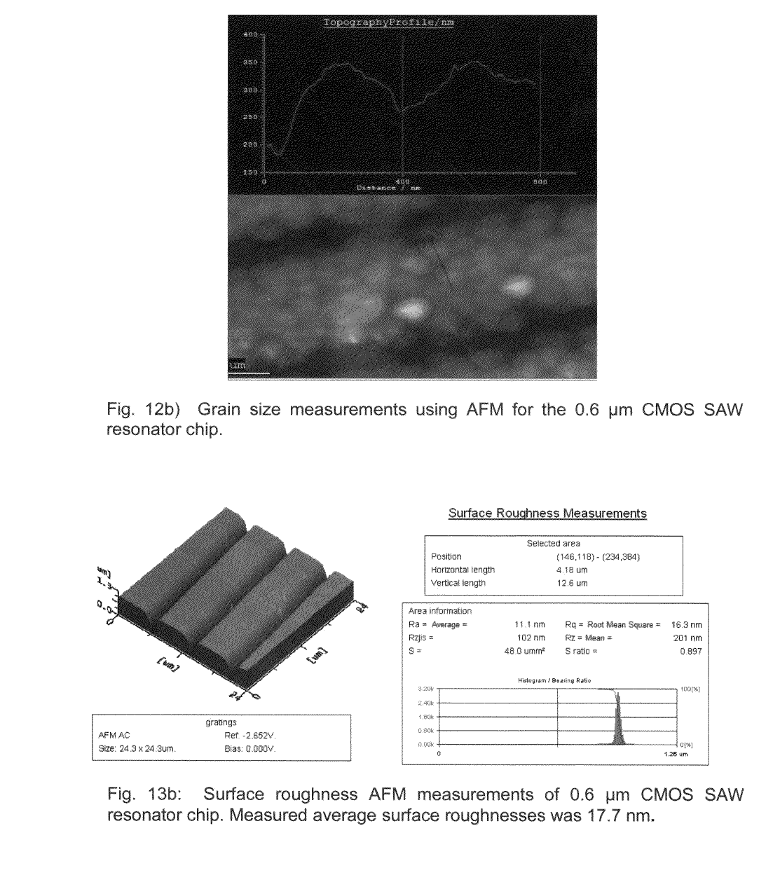

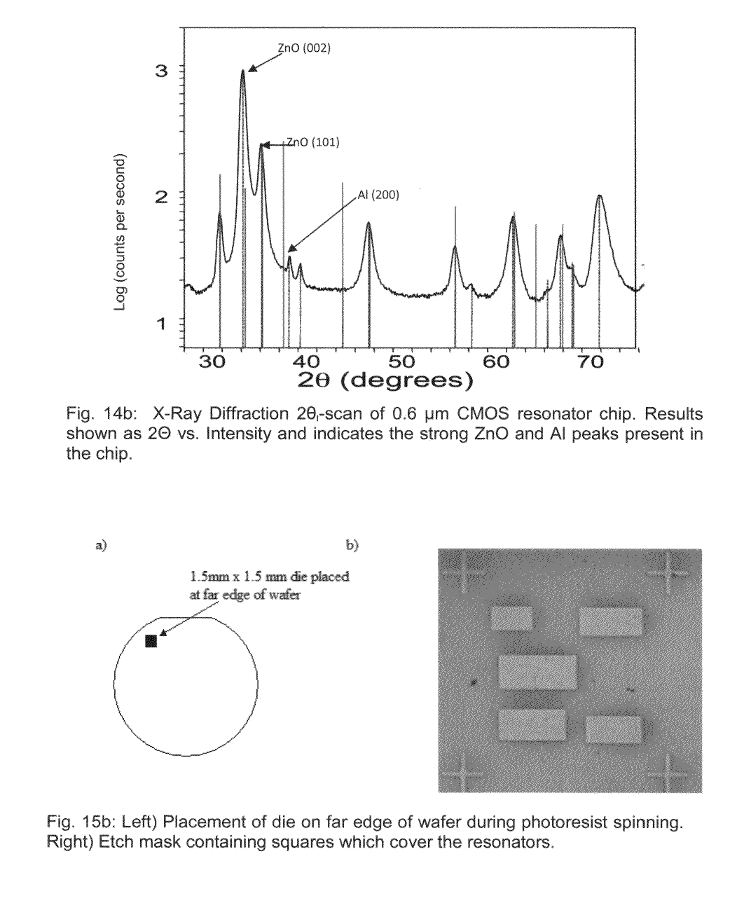

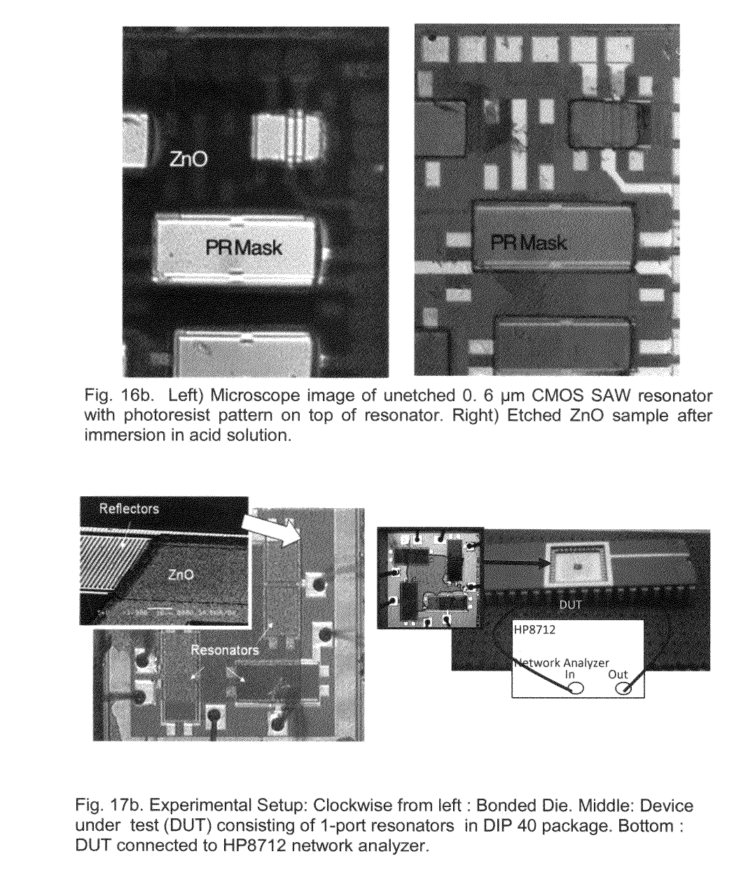

The surface morphology, roughness and the crystal orientation of the sputtered ZnO are subject of interest. Therefore, a thorough characterization of the sputtered films is required. The ZnO covered samples are analyzed for the crystal orientation in Scintag XRD 1000. For comparative analysis, 2θi scans of a dummy die (Si—ZnO) and a patterned die (Si—SiO2-Al—ZnO) were carried out. As it can be seen from FIG. 14(b), the ZnO shows its peak at 2θi=34.721, which agrees with the tabulated data in the literature for (002) 2θi=34.421. It also has a peak at 2θi=73, which corresponds to its listed peak at 2θi=72.560 for (004). In order to obtain information regarding the surface roughness and grain size JOEL High Vacuum Integrated STM/AFM/JSPM-5200 was utilized. The multilayered (Si—SiO2-Al—ZnO) dies were characterized. FIGS. 12(b) and 13(b) show the results.

C. Step 3: Patterning of the Pad Frame/ZnO Etching

After the ZnO deposition the entire die is covered with the sputtered ZnO. In order to access the pads for bonding a last step of lithography and etching are required. The entire die area is 2.2 mm×2.2 mm and the pads are 100 μm×100 μm. A simple shadow mask idea was employed for the etching step. The mask was constructed by using a square Si piece of size 2×2 mm. The major problem encountered during the patterning was the photoresist build up on the edges of the die. Thickness measurements showed a 2-4 μm phototresist buildup on the pad frame region when the thickness on the areas closer to the center of dies were measured to be 1 μm. In order to completely remove the photoresist build up covering the pad frame, a two step process was carried out. In the first step, Shipley 1818 2:1 thinner was spun for 40 sec at 5000 rpm and the samples were exposed for 20 sec. Then a 2 min development in 5:1 Developer was applied. In the second step, the same exposure time and development time was used to remove the excessive photoresist.

In general, ZnO is attacked by all common acids and bases. In order to achieve smooth etch profiles and minimize the undercutting, the etching process should be slowed. Therefore, a very dilute solution of two acids was used. The most common acids that are listed in the literature are acetic, hydrocloric and phosphoric acids. A solution of H₃PO₄:CH₃COOH:DI—H₂O with 1:1:150 was used for the etching.

2.6 μm thick ZnO was etched completely in 4 min, which translates into 648 Å/min etch rate. Once the final step of post processing was completed, the dies were bonded on a DIP-40 package for electrical testing. The major subjects of interest for performance analysis of SAW devices are the transmission coefficient and the reflection coefficient versus frequency. HP 8712ET, 300 kHz-1300 MHz, RF Network Analyzer was used for this purpose. A through-cable calibration was carried out in order to measure and compensate for the losses and errors due to the connector and cable irregularities. S11 (reflection) and S21 (transmission) coefficient versus frequency shows that the center frequency of the delay line agrees closely with the calculated value.

Thus, a test chip that contains an array of SAW delay lines were designed and fabricated in AMI 1.5 μm 2 metal, 2 poly process. A unique, three step, maskless post processing sequence was developed. Complete characterization of the two etching steps and piezoelectric film was carried out. The transfer characteristics show a maximum transmission and minimum reflection at 392.5 MHz with an insertion loss of −4.83 dB. The 3dB bandwidth was measured to be 19.25 MHz which agrees closely with the calculated value of 14.575 MHz. The results demonstrate that it is possible to design and fabricate SAW based sensors with comparable performance to conventional devices by using any commercially available CMOS technology.

CMOS Process Sequence

CMOS fabrication technology is well established and requires that both n-channel (nMOS) and p-channel (pMOS) transistors be built on the same chip substrate. To accommodate both nMOS and pMOS devices, special regions must be created in which the semiconductor type is opposite to the substrate type. These regions are called wells or tubs. A p-well is created in an n-type substrate or, alternatively, an n-well is created in a p-type substrate. In the simple n-well CMOS fabrication technology presented, the nMOS transistor is created in the p-type substrate, and the pMOS transistor is created in the n-well, which is built-in into the p-type substrate. In the twin-tub CMOS technology, additional tubs of the same type as the substrate can also be created for device optimization.

The simplified process sequence for the fabrication of CMOS integrated circuits on a p-type silicon substrate starts with the creation of the n-well regions for pMOS transistors, by impurity implantation into the substrate. Then, a thick oxide is grown in the regions surrounding the nMOS and pMOS active regions. The thin gate oxide is subsequently grown on the surface through thermal oxidation. These steps are followed by the creation of n+ and p+ regions (source, drain and channel-stop implants) and by final metallization (creation of metal interconnects).

An integrated circuit (IC) is a circuit comprised of elements such as transistors, resistors and capacitors fabricated in a single piece of semiconducting material, usually silicon or gallium arsenide. As used herein, “integrated circuit” not only refers to the common definition but also to highly integrated structures including, for example:
1) multichip modules where several IC's and other circuit elements including molecular target probes may be combined compactly on a polymer, quartz, glass, sliver, ceramic or other substrates. In some cases, one IC may be the substrate with other components, such as photodiodes or LEDs mounted on it;
2) Hybrid microcircuits where one or more IC's and other circuit elements are mounted on or several substrate(s); and,
3) Other compact electromechanical arrangements of a circuit comprising primarily one but possibly more IC's and other electronic components and microelectromechanised systems (MEMs).

### Surface Acoustic Wave Resonators

There has always been a desire, albeit not the means, to fully integrate the wireless transceiver. Surface acoustic wave (SAW) resonators have commonly been used as the local oscillator (LO) which is one of the basic building blocks of the RF receiver heterodyne architecture and is currently the major stumbling block for complete integration of RF receivers. Due to the structure of the SAW devices that require fabrication of metallized interdigital transducers on piezoelectric crystals, the SAW resonators are difficult to implement in CMOS and are usually realized as discrete off-chip components. Efforts to integrate surface acoustic wave filters on silicon substrates have been previously implemented by Visser, Vellekoop and Zeijl while the monolithic integration of SAW devices on GaAs has been implemented by Baca of Sandia National Labs.

The operating frequency of a surface acoustic wave resonator is determined by the periodic distance of its interdigitated transducer (IDT) fingers, λ, which are placed on piezoelectric material. Unlike bulk-wave crystal resonators, whose frequency of operation is determined by the thickness of the piezoelectric material, surface acoustic wave resonators have a more area efficient structure since its frequency of operation is determined by the spacing between the IDTs and thus is only limited by the resolution of the fabrication process. The utilization of surface waves, instead of bulk-waves, makes the process of integration with the present integrated circuit fabrication techniques more feasible since it eliminates the necessity of having a thick piezoelectric layer sandwiched between two metal layers.

In the present invention, implementation of surface acoustic wave resonators using the standard CMOS fabrication technology with additional post-processing techniques is provided. The fact that the fabrication process of this SAW resonator is highly compatible with current integrated circuit processing techniques makes it extremely desirable since it is not only cost-effective, but also allows the resonator features to be less prone to manufacturing defects due to the maturity of CMOS technology. In this design, the SAW resonator utilized the minimum feature sizes possible in the available 0.6 micron AMI CMOS process to realize a 1.15 GHz surface acoustic wave resonator.

The fabricated CMOS resonators were measured, and modeled as a two-port electrical network through analog circuit synthesis. This model was used as a basis for simulation in Cadence to design a Pierce oscillator. The Pierce amplifier was designed on a separate CMOS chip. When connected together, the Pierce amplifier and SAW resonator realize an oscillator capable of synthesizing a frequency of 1.15 GHz. By having both the resonator and the oscillator integrated on the same CMOS chip, a fully monolithic frequency synthesizer is realized.

### II. CMOS Surface Acoustic Wave Resonators: Design and Equivalent Circuit Model

A. SAW Resonator Design

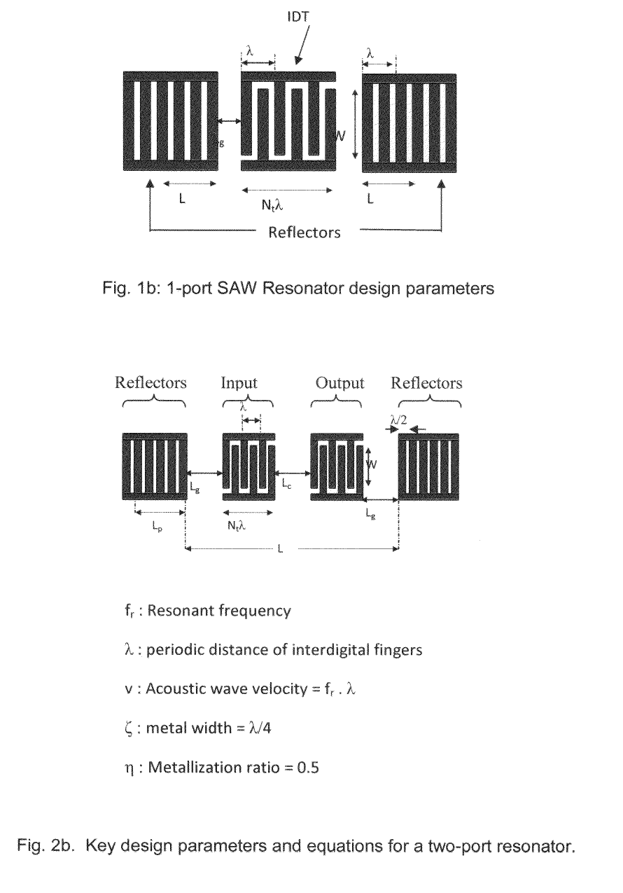

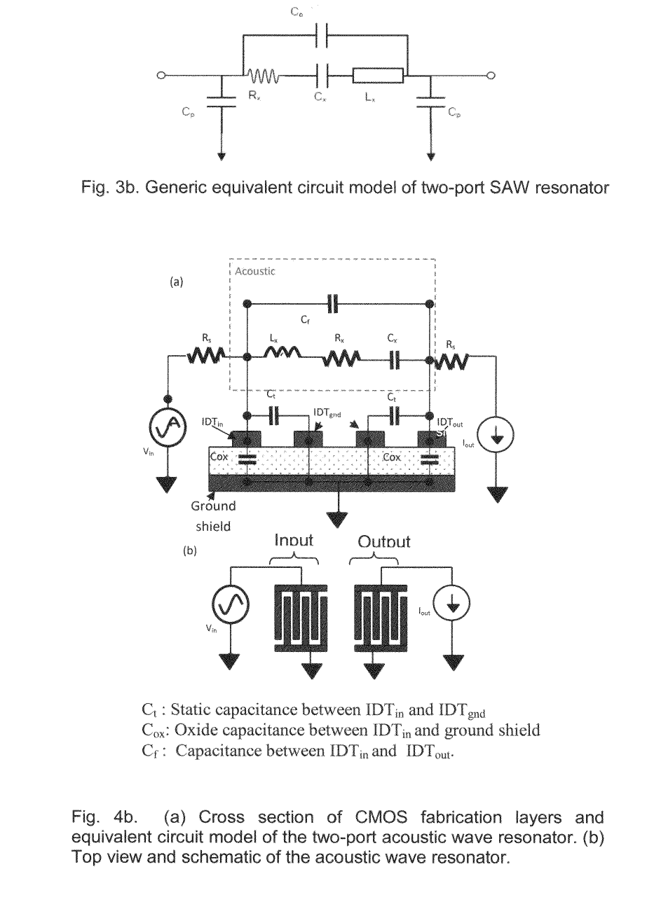

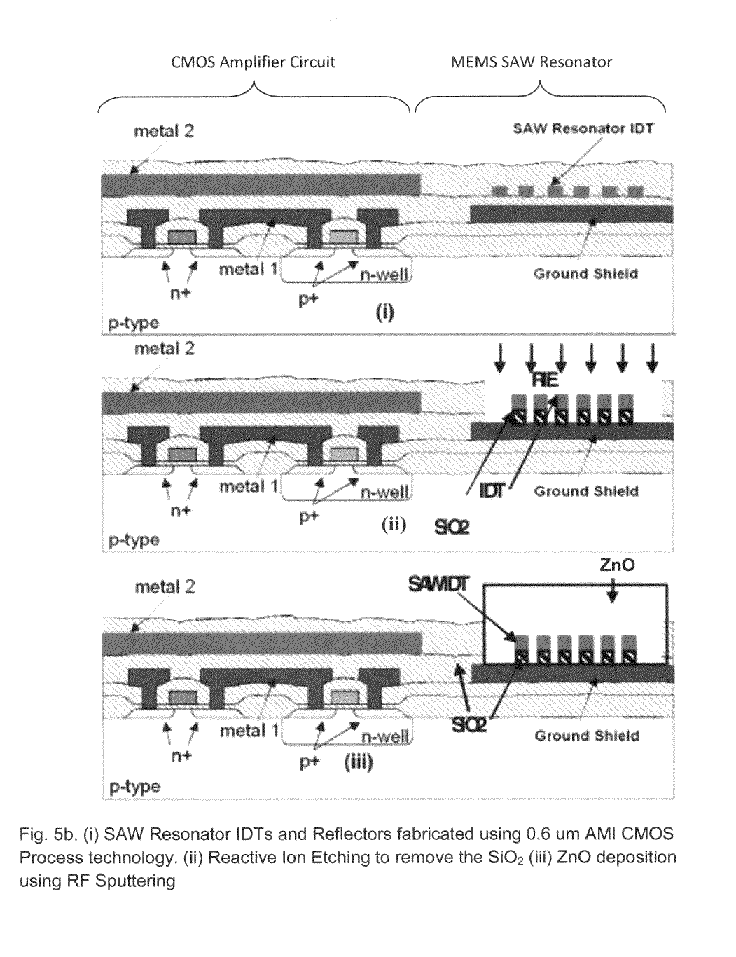

The SAW resonator design consists of input or output IDTs flanked by a bank of reflectors on both sides. Refer to FIG. 1b which illustrates the important design parameters of a 1-port resonator. The key design parameter is λ, or the periodic distance between two interdigitated fingers, which determines the frequency of the resonator, using v=fλ, where v is the velocity of the acoustic wave in the piezoelectric material and f is the resonant frequency. In this design run, λ was chosen to be four times the minimum metal2 size of this technology or 3.6 micron. The modeling equations for SAW resonators, which involve rigorous computations of transmission matrices, will not be discussed in detail in this paper but the basic methodology of designing the SAW resonators and its accompanying oscillator circuit is outlined here.

The main design parameter that needs to be chosen is M or the number of reflectors. An array of reflectors is required since each electrode only produces reflectivity, r of approximately 0.08. The equation for reflectivity was derived based on the theory of reflection in transmission lines, and is given in Formula (1A), where η is the metallization ratio of the IDT, Z is the characteristic impedance of the region under the reflector, ΔZ is the difference of characteristic impedance between the free region and the region under the reflector, and finally, fᵣ is the resonance frequency.

$$\begin{matrix}r - j \frac{Δ Z}{Z} sin ( ηπ \frac{f}{{f}_{r}} ) & \begin{matrix}( 1 ) \\ ( 1 A )\end{matrix} \\ Γ ∼ tanh ( M ) & ( 2 A ) \\ L = 1 / ( 4 \vert r \vert ) & ( 3 A )\end{matrix}$$

The array reflectivity, r can also be approximated as Formula (2A) and the number of reflectors was chosen to optimize area while maintaining array reflectivity to be close to 1. The effective center of reflection, or the line where the surface waves are assumed to be totally reflected is denoted by L is expressed as Formula (3A) where r is the reflectivity of each electrode. MATLAB simulations of (I A), (2A) and (3A) using ZnO thin film material properties were performed to obtain the optimum number of reflectors which was found to be 125 for this design. The total effective length of a round trip in the cavity must be an integer number of λ. Other important design parameters are the distance between the reflectors and the input transducers Lg, the number of IDTs or Nₜ and the width of the transducers or W. Thirty-two different designs of SAW resonators were first fabricated on piezoelectric substrates such as lithium niobium substrates to evaluate the performance of the fabricated designs. Four resonators with the best performance characteristics were then chosen and scaled to fit the 0.6 um CMOS in this design run.

TABLE 1
CMOS SAW 2-PORT RESONATOR DESIGN PARAMETERS

| | λ | fᵣ | W | | Lg | Lc |
|---|---|---|---|---|---|---|
| Resonator | (μm) | (GHz) | (μm) | N | (μm) | (μm) |
| 1 | 3.6 | 1.000 | 144 | 39 | 7.2 | 7.2 |
| 2 | 4.2 | 0.857 | 168 | 100 | 1.05 | 2.1 |
| 3 | 6 | 0.600 | 160 | 33 | 1.5 | 3 |

### B. Equivalent Circuit Model

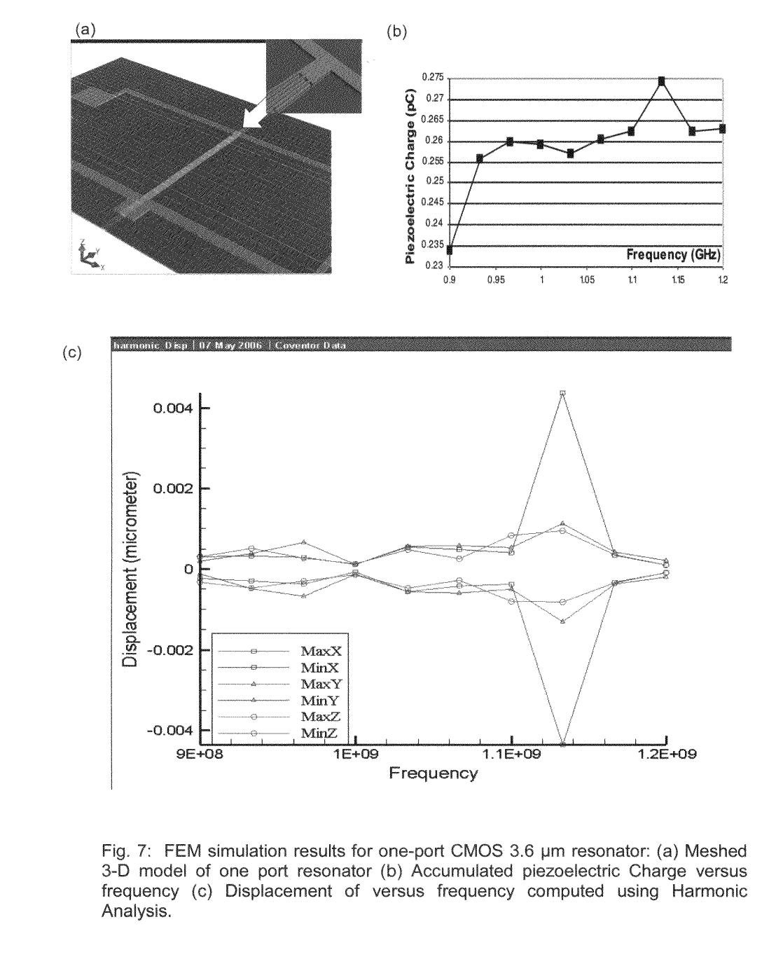

The equivalent circuit model of a two-port SAW resonator was developed using analog circuit synthesis based on the S21 frequency measurements made on the fabricated CMOS resonators. The SAW resonator has transmission characteristics similar to a series LCR circuit, where the series resonant frequency is generated by both Lₓ and Cₓ. The initial values for the LCR circuit were calculated using the resonator design equations based on the reflectivity of each metal strip and number of reflectors. This basic LCR circuit was then modified based on curve fitting, where the simulated values were compared with the experimental measurements. Several circuit topologies were implemented an least squares method was used to choose the circuit, which produced the best fit. The final circuit topology that produced the best fit may be determined where it consists of Rx, Cx and Lx which are motional resistance, capacitance and inductance connected in parallel with Lp and Rp. The input and output ports are connected with parasitic capacitances Cp to ground. The circuit's S21 scattering parameters analysis simulations were performed using Cadence SpectreRF where the input and output ports were terminated with 50 Ohms. Comparison between the measured and simulated equivalent circuit model is shown in FIG. 7b. The best fitting curve was found to have the values of Lx=1 uH, Rx=120 Ohms, Cx=19 fF, Lp=132.8 nH, and Cp=10 fF.

### III. Fabrication

Perhaps the most important highlight of this SAW resonator design is that the SAW resonator IDT's can be implemented using standard CMOS technology. This allows the resonator features to be realized in the minimum sizes available in the AMI 0.6 micron CMOS process, making them not only less susceptible to manufacturing defects but also less expensive compared to when fabricated as micromachined MEMS structures. The resonator features were implemented as 0.9 micron wide metal2 lines which are able to realize ultra-high frequency, 1.15 GHz resonators.

The SAW CMOS post fabrication sequence is similar to the CMOS SAW delay line, with several important distinctions, namely the presence of the aluminum ground metal1 shield which was placed to eliminate electromagnetic feed-through. The other major difference is the presence of the oscillator circuit which is also placed on the same die and protected by a grounded metal layer as shown in Chip B shown in FIG. 9(b).

Once the standard CMOS fabrication sequence is completed, the first post-processing step involves releasing the SAW IDTs from the insulating SiO2 layer using reactive ion etch (RIE). The next step is ZnO deposition, which was sputtered on the resonators. The final post-processing step involves wet-etching the ZnO to uncover the resonators' pads.

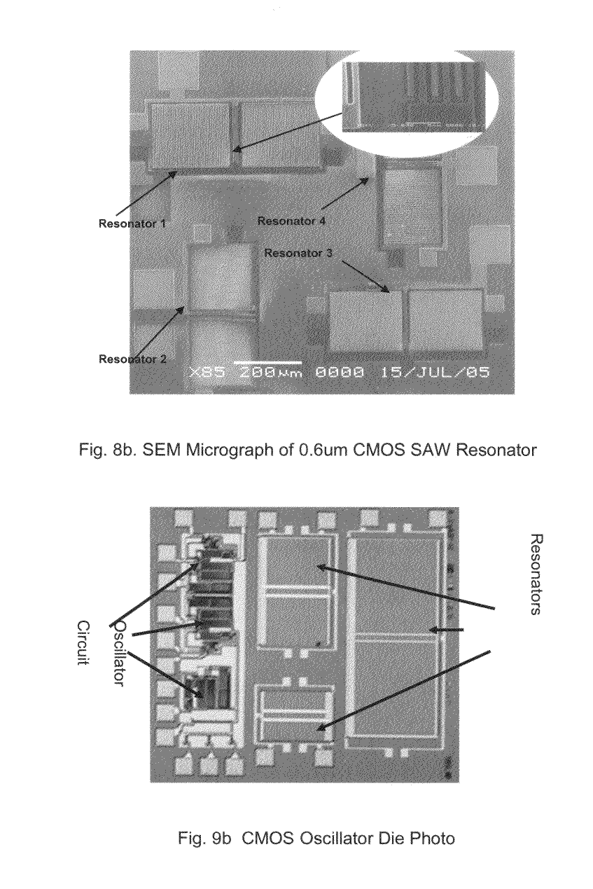

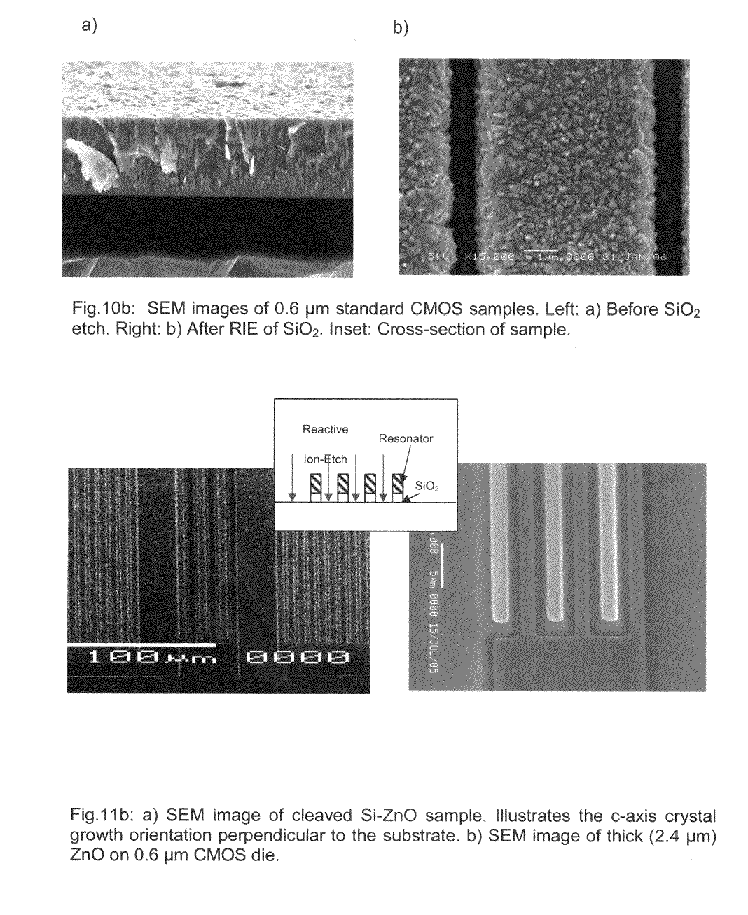

Two separate CMOS chips had been designed. The first chip shown in FIG. 8(b) (Chip A) consists of four CMOS SAW resonators was fabricated and characterized prior to the design of the second chip. Chip B which consists of three resonators and the Pierce oscillator circuit is shown in FIG. 9b. Chip A was designed to characterize the ultra high frequency resonator of frequencies in the range of 900 MHz to 1.2 GHz. Chip B was implemented as a proof of concept that the post-processing techniques of the SAW resonator do not adversely affect the amplifier circuit.

### IV. Experimental Results and Discussion

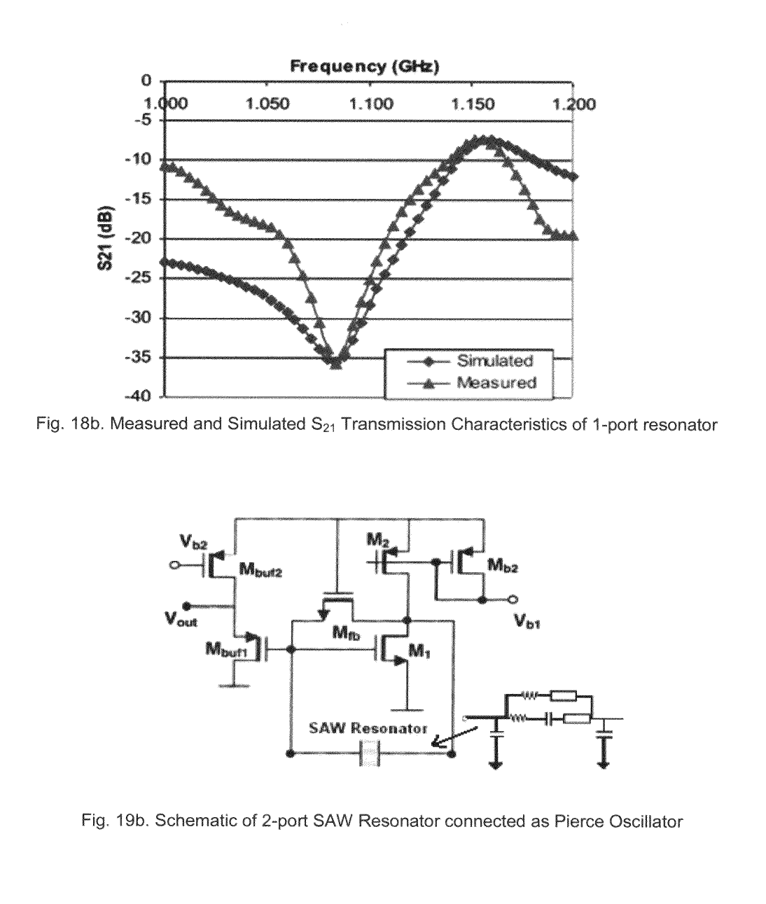

Once the post-processing steps have been completed, the die was bonded and packaged in a DIP40 chip package to facilitate measurements. The bonded device was measured using a HP8712 network analyzer and its experimental setup is shown in FIG. 17b. The S21 measurements made on the 0.6 micron CMOS SAW resonators produced the parallel resonance frequency, fp of 1.084 GHz and the series resonance frequency, fs of 1.156 GHz as shown in FIG. 18b. Based on the measurements, the parallel Q was calculated to be 90.33 and series Q was calculated to be 36.125. The measured Q was not as high as expected since the die was overetched and some parts of the resonator was not completely covered as shown in the bonded die image of FIG. 17b. The acoustic wave velocity of ZnO calculated from the measured curve was found to be 4140 m/s.

### V. Oscillator Design and Simulation

To operate as a local oscillator, the SAW resonator is connected to a Pierce oscillator at the gate and drain of M1 as shown in FIG. 19b. This three-point oscillator topology was previously implemented using an FBAR oscillator by Otis, and was chosen firstly since it utilizes the current source, M2 to provide the necessary biasing current to M1, as the SAW resonator does not pass any DC current. Secondly, it also provides excellent phase noise characteristics. Mfb, operates as a resistor which provides bias to the gate of M1.

A_{CL}=gₘRₚ(Cₚ₁/Cₚ₂) (4A)

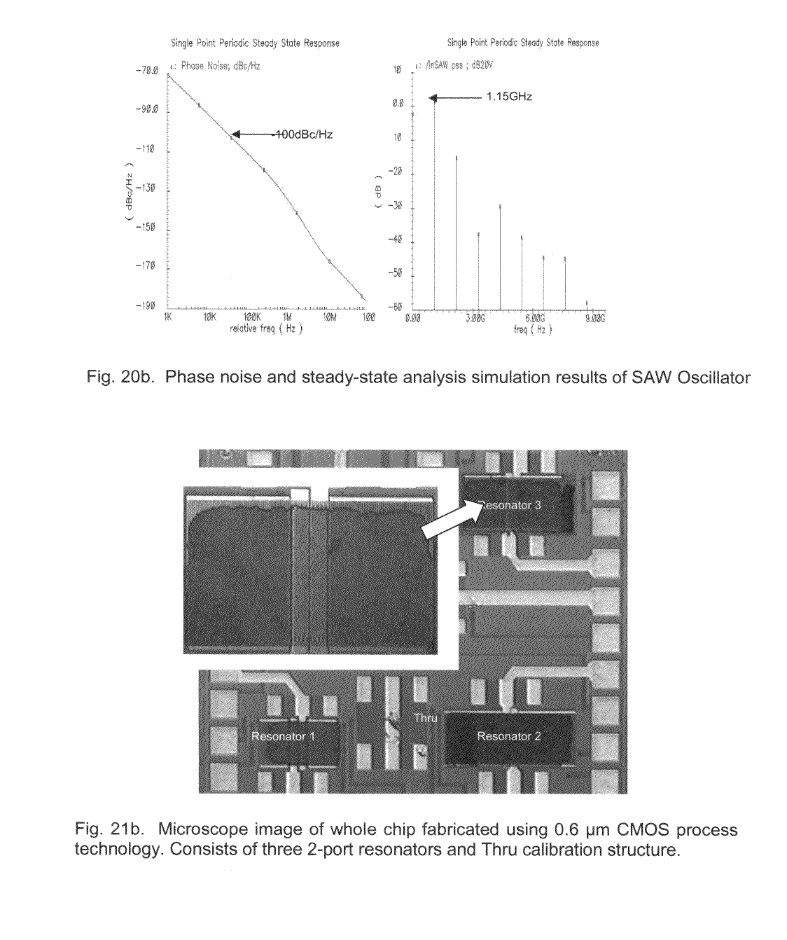

To ensure oscillation, the loop gain, A_{CL} has to be greater than 1 and the phase shift should be equal to 0. Based on Formula (4A), the size of M1 is adjusted to provide the necessary transconductance to counteract Rₚ, where Rₚ is the parallel reflected motional resistance at the gate of M1. For this design Cp1=Cp2 which also maximizes the open loop gain. The transistors were sized as follows, M1=4.8 m/1.6 u, M_{fb}=4 u/872 u, M2=9.6 m/1.2 u. The phase noise performance and steady-state analysis of the oscillator circuit was simulated using Cadence SpectreRF to obtain its fundamental beat frequency of 1.154 GHz are shown in FIG. 20b.

Accordingly, the design, implementation and measurements of a CMOS SAW resonator is provided. The SAW resonators were fabricated using standard AMI 0.6 micron CMOS technology with some additional post-processing steps. Upon completion, the SAW resonators were characterized and found to have a resonant frequency of 1.15 GHz and its equivalent circuit model was developed based on these measurements. This model was used to design and simulate a Pierce 1 GHz oscillator.

### Examples

In these example implementations, one deposition step is eliminated since standard CMOS metal layers are used to implement the transducers' structures. The maturity and precision of the standard 0.6 μm CMOS technology enables us to manufacture very well-defined metal features to implement the transducers, with minimum widths of 0.9 μm, resulting in very high frequency resonators of 1.02 GHz.

These examples present the design, fabrication, equivalent circuit model and characterization measurements of three two- port resonators.

### Example I

The design of the CMOS SAW resonators is described first, where the key design factors that affect the resonant frequency and quality factor are highlighted. Next, the fabrication sequence of implementing the surface acoustic wave resonators in CMOS with three additional post- processing steps is illustrated in detail. Characterization of the piezoelectric zinc oxide layer using x-ray diffraction, scanning electron microscopy (SEM) and atomic force microscopy is also reported. The fabricated resonators were measured to obtain its S₂₁ and S₁₁ transmission and reflection characteristics. To verify the resonant frequency of the device, finite element modeling of the device was also done using CoventorWare®. Based on the measurement results and the fabrication layers of the CMOS resonators, an equivalent circuit model specifically for two-port CMOS surface acoustic wave resonators was developed. Simulations using the developed equivalent circuit were compared with the experimental measurements of the fabricated device.

### Example—II

### Resonator Design

A. Resonator Structure

The structure of a two-port CMOS SAW resonator consists of input and output interdigital transducers, which are flanked by a bank of shorted reflectors on each side. Shorted reflectors have been shown to have less spurious effects compared to unconnected reflectors and have been used in all our designs.

When a sinusoidal signal is injected at the input port, acoustic waves propagating in both directions are generated in the piezoelectric zinc oxide layer. The acoustic waves are detected and translated back into an electrical signal at the output port. The reflectors minimize the losses by containing the acoustic waves within the cavity, to create standing waves or resonance.

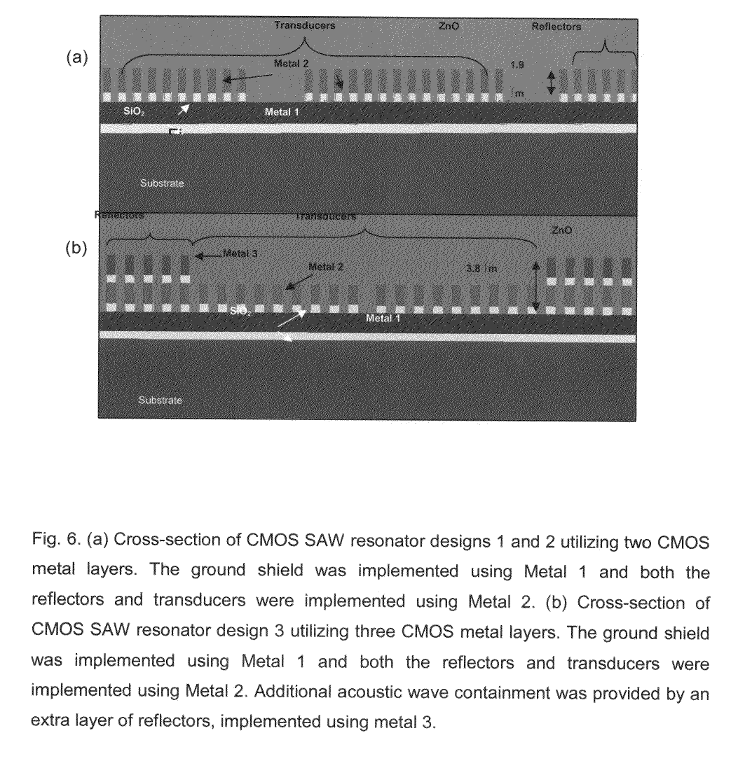

FIG. 6(b) (a) illustrates the cross-section of the CMOS resonator implemented for design 1 and design 2. This implementation utilized two CMOS metal layers, namely metal 1 for the ground shield and metal 2 for the reflectors and transducers. In an effort to improve the quality factor of the device, the third resonator utilized all three available metals in the CMOS 0.6 μm technology. For this implementation, as shown in FIG. 6(b) (b) both metal 2 and metal 3 were used as reflectors to contain the acoustic waves propagating above the transducer.

B. Resonator Design

The schematic of a two-port resonator, its important design parameters and equations are shown in FIG. 2b. For preliminary design, the acoustic wave velocity was assumed to be 3600 m/s. The highest resonant frequency that can be designed for the CMOS 0.6 μm technology used the minimum metal 2 feature size of 0.9 μm for the interdigital finger width (λ/4). The periodic spacing of the interdigital transducers is then calculated as λ=3.6 μm and is shown in Table 1 as Resonator 1. It is assumed that the acoustic wave will penetrate the reflector array for a length of Lp, at which point the wave will be totally reflected. Table 1 illustrates the design parameters of the three implemented resonators. The designs varied λ, to verify the relationship between the fr and λ. The designs also varied the number of reflectors (N).

TABLE 1
CMOS SAW 2-PORT RESONATOR DESIGN PARAMETERS

| | λ | fᵣ | W | | Lg | Lc |
|---|---|---|---|---|---|---|
| Resonator | (μm) | (GHz) | (μm) | N | (μm) | (μm) |
| 1 | 3.6 | 1.000 | 144 | 39 | 7.2 | 7.2 |
| 2 | 4.2 | 0.857 | 168 | 100 | 1.05 | 2.1 |
| 3 | 6 | 0.600 | 160 | 33 | 1.5 | 3 |

### Example—III

### Resonator Post-CMOS Processing

The SAW resonator fabrication can be described using three step post-CMOS fabrication process. In this work, 0.6 μm American Microsystems Incorporated (AMI) CMOS 3-metal, 2-poly process was used. Standard CMOS layers were used to implement the resonator's interdigital transducers, reflectors and the ground shield, which are implemented using metal1 and metal2 CMOS, respectively. The ground shield is crucial for elimination of electromagnetic feed-through and isolation from substrate noise. For future integration with circuits, all post-processing steps were carefully selected such that no process will require temperatures greater than 4000 C to ensure compatibility with the integrated circuitry. Circuits can be implemented using metal 1 and metal 2 with metal 3 as protection against the adverse effects of the post-processing.

A. Reactive-Ion-Etching

The first post-processing step requires releasing the SAW electrodes from the insulating SiO2 layer. It was reported that reactive-ion-etching (RIE) can be used to remove oxide between interdigital transducer fingers. Timed RIE process was used to etch the 2.5 μm thick oxide layer. The calculated etch rate was 0.2174 μm/min, which was sufficient to remove all the oxide surrounding the metal electrodes. Contact test was performed to ensure complete release of the metal electrodes. FIG. 11b shows the complete removal of SiO2 from the interdigital fingers and reflectors.

B. Zinc Oxide Deposition and Characterization

Zinc oxide has been chosen as the piezoelectric material due to is superior acoustic propagation and transduction compared to other integrated-circuit compatible piezoelectric layers such as AlN . To obtain maximum piezoelectric coupling, 2.0<khZnO<4.2 where k=2π/λ. For our designs of 3.6 μm <λ<6 μm, the optimum thickness of zinc oxide was calculated to be 2.4 μm.

Zinc oxide deposition was performed using radio frequency (RF) magnetron sputtering, where the 2.4 μm thick ZnO layer was deposited at a rate of 0.297 μm/hr over the entire die area. Sputtered ZnO films are preferred since these layers are highly oriented and dense. The temperature of the sample was kept below 4000 C to ensure compatibility with the integrated circuitry. The sputtering was conducted with 50/50 gas flow mixture of Ar/O2 with power of 150 W.

To evaluate the quality of the ZnO, the X-ray diffraction 2θι-scan was performed on the deposited ZnO on CMOS SAW resonator samples to determine the ZnO's crystal orientation. Highly oriented ZnO films produce high reflection intensity from the (002) planes and have been reported to have good piezoelectric coupling coefficient κ. FIG. 14b illustrates the results of the X-ray diffraction test performed on the 0.6 μm CMOS SAW resonator sample. The reflection intensity of each phase is measured in log scale of counts per second. It indicates that the ZnO crystals are oriented at the (002), since the highest peak occurs at 34.20 with 2.9 counts per second (cps). The Al layer has its peak at (200) where θ=44.720. The surface morphology of the zinc oxide layer was also investigated using atomic force microscopy, where the root mean-square roughness of the layer was measured to be 0.05 μm.

C. Zinc Oxide Etching

The ZnO covered die was wet-etched to enable access to the resonator's pads for probing. The resonator area is masked using standard lithography process using 1.8 μm thick liquid photoresist. The small size (1.5 mm×1.5 mm) of the samples creates a tendency of photoresist buildup at its edges. To solve this, the small die is first glued at the far edge of a large circular wafer before photoresist spinning. The die and wafer are spun at 4000 rpm. This method produces uniform photoresist throughout the sample. The sample is then patterned by placing the sample in a mask aligner and exposed to ultraviolet light for 18 s. The mask is a set of three squares, which only covers the resonators. The sample is placed in developer solution for 60 s to develop the pattern. Once the protective photoresist has covered the resonator, the sample is immersed in an etching solution, which is selective to the photoresist. To etch the zinc oxide, an etching solution that does not adversely affect the piezoelectric properties of ZnO is required. The H3PO4:C6H8O7:H2O solution have been reported to produce very steep etch slopes. This etching solution with concentrations 1:1:80 was used to etch the sample for 158 s. The calculated etch rate was 1.4 μm/min. The SEM image of the etched ZnO illustrates very well defined etched edges of the piezoelectric ZnO layer.

### Example—IV

### Resonator Modeling and Simulation

Equivalent Circuit Model

Based on the fabrication layers of the device and the equations derived by Morgan, Zeijl and Datta, the equivalent circuit model tailored specifically for standard CMOS two-port resonator was developed. The equivalent circuit for the resonator can be divided into two distinct parts, namely the acoustic and the parasitic components.

The acoustic component describes the propagation of the acoustic wave within the cavity. The acoustic waves, generated by the interdigital fingers propagate in the piezoelectric layer and act as a resonator and consist of Cx, Rx, Lx and Cf.

The parasitic component consisting of Rs, Cox and Ct exist due to the structure and the layers of the resonator. As shown in FIG. 4b, the interdigital fingers were constructed using metal 2 layer on top of SiO2. Underneath the oxide is the ground metal 1 shield. This structure creates two parasitic capacitances namely Ct and Cox. The electrostatic capacitance (Ct) is the capacitance of the parallel plates of the interdigital transducers and is described in (2). Ct is proportional to the width of the aperture (W) and the number of transducer pairs (Nt). Since the capacitive parallel plates of the interdigital transducers are placed within the piezoelectric material, the relevant permittivity constant (ε) is the effective dielectric permittivity of zinc oxide, ε=135 pF/m.

(1)

Cₜ=WεNₜ (1)

Cox is the oxide capacitance between the input and output port and the ground shield and is calculated using (2). Cox is not present between IDTgnd and the ground plane since in our design, there exists a via or connection between IDTgnd and the ground plane. It is assumed that the resistance at the input (Rf) is the impedance of the network analyzer or 50 Ohms.

Cₒₓ=Wεₒₓ N̅ₜ (2)

As shown in FIG. 4(b) when a sinusoidal signal Vin is applied to the input port, propagating acoustic waves will be generated in the piezoelectric layer above the interdigital fingers. The incident acoustic waves will induce current lout in the output port. The ratio Iout/Vin is known as the admittance (Yt). The real part of the admittance is known as radiation conductance, which represents electrical-to-acoustic energy conversion. The radiation conductance (Ga) at resonant frequency (fr) is approximated as in (3).

Gₐ=8κ²fᵣCₜNₜ² (3)

The piezoelectric coupling coefficient (κ) was obtained from where the phase velocity (v) and κ have been calculated and graphed for the multi-layer ZnO—SiO2-Si structure with varying ZnO thicknesses. κ2 has values ranging from 0 to 0.032. For this design, κ2=0.017.

The interdigital fingers are placed within a cavity formed by the reflectors. The reflectors contain the acoustic waves within the cavity, reducing the losses of the acoustic waves propagating outwards. To describe the effect of these reflectors, the reflectivity (r) a single strip was calculated. The expression used to describe the reflectivity in an array of short-circuited reflectors was provided by Datta in and is shown in (4). The variables used in (4) were defined as follows where Δ=ηπ and the Legendre polynomials were calculated as P0.5(cos Δ)=1.5061 and P−0.5(cos Δ)=1.3280. For this design, the metallization ratio, η was set to 0.5. The array reflectivity is described using (5) and is a function of both r and the number of reflectors (N).

$$\begin{matrix}r = j \vert \frac{1}{2} {κ}^{2} \vert \frac{π}{2} ( ( - cos Δ ) + \frac{{P}_{0.5} ( cos Δ )}{{P}_{- 0.5} ( - cos Δ )} ) & ( 4 ) \\ \vert Γ \vert ≅ tanh N \vert r \vert & ( 5 )\end{matrix}$$

All the equations above were coded into MATLAB® to determine the device's array reflectivity (Γ). For resonator design 1, r was found to be 0.01511 and Γ=0.8278 where λ=3.6 μm, N=39 and κ2=0.017. Since Γ<1, the acoustic wave will penetrate the reflector array till a point Lp, where it is assumed that the wave is totally reflected. The effective penetration length, Lp was calculated using (6). For resonator 1, Lp=59.436 μm.

$${L}_{p} = \frac{λ}{4 \vert r \vert} \qquad ( 6 )$$

The acoustic wave variables Cx, Rx and Lx are based on the transmission line model provided by Zeijl and Datta. Near fr, the device acts as a resonator, which can be modeled as an LC tank circuit. Rx is the inverse of the radiation conductance of the interdigital transducers (Ga). Due to the effect of the reflectors, Ga is increased by a factor related to the array reflectivity (Γ) and δ which is half of the effective cavity length as shown in (7) and (8).

$$\begin{matrix}{G}_{s} ( {f}_{r} ) = {G}_{a} \frac{1 + 2 Γ cos ( 4 π δ / λ ) + {Γ}^{2}}{1 - {Γ}^{2}} & ( 7 ) \\ δ = {L}_{g} + {L}_{p} + \frac{{N}_{t} λ}{2} & ( 8 )\end{matrix}$$

The acoustic resistance Rx is inversely proportional to Gs and was described in (9). The inductance (Lx) described in (10) is related to the total effective cavity length (L+2Lp), Γ, Ga, δ and the acoustic velocity (v). Since the device is a resonator, the acoustic capacitance (Cx) is a function of Lx as described in (11). Due to the proximity of the input and output port, a feedthrough capacitance (Cf) exists and determines the parallel resonance frequency (fp). Cf can be calculated using (12) where t is the thickness of metal 2 and was defined as 1.6 μm.

$$\begin{matrix}{R}_{x} = \frac{1}{{G}_{s} ( {f}_{r} )} & ( 9 ) \\ {L}_{x} = \frac{L + 2 {L}_{p}}{{G}_{a} v} \cdot \frac{{Γ}^{2}}{1 + 2 Γ cos ( 4 πδ / λ ) + {Γ}^{2}} & ( 10 ) \\ {C}_{x} = \frac{1}{4 {π}^{2} {f}_{r}^{2} {L}_{x}} & ( 11 ) \\ {C}_{f} = \frac{ɛ W t}{{L}_{c}} & ( 12 ) \\ Q = \frac{2 π}{λ} ( L + 2 {L}_{p} ) \frac{{Γ}^{2}}{1 - {Γ}^{2}} & ( 13 )\end{matrix}$$

The quality factor of the resonator is a function of the total effective cavity length (L+2Lp) and array reflectivity (Γ) as shown in (13). A summary of the equivalent circuit model values is shown in Table 2. In comparison with Table 1, the resonators were designed to maximize Γ without occupying too much area. Based on (4), array reflectivity (Γ) close to 1 can be achieved by having a many reflectors, at the expense of consuming large area. Resonator 2 with N=1100, has the maximum Γ and correspondingly the highest Q.

TABLE 2
CMOS SAW 2 - Port Resonator Design RLC

| | | | | | | Cₒₓ + Cₜ | | | | |
|---|---|---|---|---|---|---|---|---|---|---|
| Resonator | λ (μm) | Rₓ (kΩ) | Cₓ (aF) | Lₓ (μH) | C_{f} (fF) | (pF) | Γ | Qₛ | fₛ (MHz) | fₚ (MHz) |
| 1 | 3.6 | 2.16 | 332 | 71.6 | 5.6 | 0.238 | 0.83 | 684 | 1042.9 | 1032.2 |
| 2 | 4.2 | 13.0 | 48.5 | 603 | 22.4 | 0.278 | 0.99 | 29059 | 930.92 | 930.95 |
| 3 | 6 | 7.56 | 208 | 335 | 14.9 | 0.265 | 0.87 | 683 | 602.40 | 603.76 |

B. Finite Element Simulation

The resonant frequency of the device was verified using CoventorWare®'s three-dimensional finite element method analysis. The device was modeled as an electromechanical system where the solver was used to compute mechanical displacement in the piezoelectric layer due to an electrical excitation. The resonant frequency of the device occurs when there is maximum displacement of the piezoelectric layer in all directions. To model the composite resonator structure, a seven-step fabrication process describing CMOS and its MEMS post-processing was utilized and are shown in Table 3.

TABLE 3
CMOS SURFACE ACOUSTIC WAVE RESONATOR
FABRICATION LAYERS

| | | Layer | Material | Thickness |
|---|---|---|---|---|
| | Step Name | Name | Name | (μm) |
| 0 | Substrate | Substrate | SILICON | 50 |
| 1 | Stack Material | SiO₂ | OXIDE | 0.6 |
| 2 | Conformal Shell | CMF | Al (Film) | 1.5 |
| 3 | Stack Material | SiO₂ | OXIDE | 0.6 |
| 4 | Conformal Shell | CMF | Al (Film) | 1.6 |
| 5 | Straight Cut | | | |
| 6 | Planar Fill | ZnO | ZnO | 2.4 |

Layers 0-4 describes the resonator's layers implemented using CMOS, while layer 5 and layer 6 describe the reactive-ion-etching and RF sputtering of the ZnO layer respectively. The piezoelectric strain matrix coefficients used for the ZnO were d31=−5.43×10-6, d32=−5.43×10-6, d33=1.167×10-5, d24=−1.134×10-5 and d15=−1.134×10-6 [16].

The device's resonant frequency can be determined using harmonic analysis in CoventorWare®. Harmonic analysis provides the structure's response to a continuous harmonic excitation. For resonator 1, harmonic excitation was applied as a sinusoidal waveform of 3 V amplitude with frequencies between 1 GHz to 1.3 GHz at the resonator's interdigital transducers. Due to the piezoelectric properties of the zinc oxide layer, the induced electrical excitation will produce mechanical displacement, which in turn generates the surface acoustic wave in the ZnO layer. The maximum displacement in all directions occurs at 1.13 GHz for resonator 1 with λ=3.6 μm and can be compared to its design series resonant frequency of 1.0320 GHz as shown in Table 2. The propagating acoustic wave in the piezoelectric layer has maximum displacement of 0.004 μm.

### Example—V

### Experimental Measurements and Discussion

The designed chip consisting of three resonators is shown in FIG. 21b. To obtain S21 and S11 measurements, each resonator was probed using two coplanar G-S-G probes in the Cascade Microtech 9500 Parametric Probe Station connected to the HP8712 network analyzer. The coplanar probes were connected to the network analyzer using cables, SMA and N connectors. The experimental setup is shown in FIG. 22b.

A Thru calibration structure was also included in the design to improve measurement accuracy. Both metal 2 and metal 1 in CMOS was used to implement the Thru structure. To avoid the probes crashing and damaging one another, the distance between the two probes was set to be 200 μm.

A. Analysis of Measurement Results

The S21 measurements provide the insertion loss (IL), series resonant frequency (fs) and parallel resonant frequency (fp). The S21 transmission magnitude and phase measurements as well as the S11 reflection measurements of resonators 1, 2 and 3 are shown in FIG. 23b and FIG. 24b respectively. Resonator 3 shown in FIG. 23b (c) exhibited the best transmission characteristics, having the highest parallel quality factor of 284.98. The high quality factor of this resonator is due to its structure, where an additional layer metal 3 of reflector was implemented as shown in FIG. 22(b). Based on Morgan, the maximum energy of the propagating acoustic wave is within λ thickness of the piezoelectric layer. For our design, the thickness of ZnO was 2.4 μm and it is assumed that the energy of the acoustic wave is contained within the entire thickness of the piezoelectric layer. The first layer of reflector structure constructed using metal 1 has a total height of 1.9 μm which is insufficient to reflect all the propagating acoustic waves. Stacking an additional metal 3 layer of 1.6 μm with additional 0.3 μm layer of SiO2 will result in a total height of 3.8 μm of for the reflector structure. This height is greater than the thickness of the sputtered ZnO layer and is sufficient to reflect all the energy of the propagating acoustic wave. This results in suppression of harmonics, having a single parallel and series resonant frequency as shown in FIG. 23b.

Resonator 1 shown in FIG. 23b (a) exhibits transmission characteristics which are not well-defined, having very low Qs and Qp of 33.32 and 44.43 respectively. The low Q can be attributed to both the insufficient height of the reflectors as well as the design. With reference to Table 1 where both Lg and Lc of Resonator 1 was set to 7.2 μm or 2λ. This results in a distorted wave since L/λ=17 is not an odd multiple of λ/2. Much improved resonant characteristics are seen in both Resonator 2 and Resonator 3 where L/λ=10.5 for both resonators as shown in FIG. 23b (b) and (c) respectively.

B. Measurement of Surface Acoustic Wave Velocity

In comparison to Table 1, the resonators were designed to have series resonant frequencies of 1 GHz, 857 MHz and 600 MHz respectively. The measured resonators had series resonant frequencies of 1.032 GHz, 930 MHz and 602 MHz respectively. The difference between the design and measured resonant frequencies can be attributed to the deviation of the acoustic wave velocity value from the assumed 3600 m/s. The acoustic wave velocity of the device can be extracted from the measured fs based on v=fsλ. Table 4 shows the variation of surface acoustic wave velocity at different λ. The acoustic wave velocity is a function of khZnO where k=2π/λ and hZnO is the thickness of the ZnO layer. For this chip hZnO=2.4 μm. It has been shown in that both the acoustic wave velocity and the piezoelectric coupling coefficient (κ) is a function of khZnO, where the optimum is between 2 and 4.2. It can be seen from the Table 4 that at khZnO=3.5904, the extracted acoustic wave velocity is at its highest, indicating the maximum piezoelectric coefficient. This indicates that to obtain maximum coupling, each design with different λ should have different thickness of zinc oxide. This however, is impractical for this chip since all the resonators with different λ were placed on the same chip and had to have a constant hZnO for all three designs. This resulted in different κ and different acoustic wave velocity for each resonator.

TABLE 4
EXTRACTED SURFACE ACOUSTIC WAVE
VELOCITY AT DIFFERENT λ

| λ | (2π/λ) · h_{ZnO} | Measured fₛ | Extracted SAW velocity |
|---|---|---|---|
| 3.6 μm | 4.1888 | 1.03275 GHz | 3717.9 m/s |
| 4.2 μm | 3.5904 | 0.93094 GHz | 3909.9 m/s |
| 6 μm | 2.5133 | 0.60256 GHz | 3615.4 m/s |

C. Extraction of Equivalent Circuit Parameters from S21 Measurements

The S21 measurements can also be used to extract the equivalent RLC circuit parameters of the resonators [20], [21 ]. The S21 measurements can be used to calculate the series quality factor (Qs) and parallel quality factor (Qp) based on the 3 dB bandwidth at the series and parallel resonant frequencies respectively, Q=f/Δf3dB. Based on the equivalent circuit model shown in FIG. 4b, the equations of the impedances for the equivalent circuit can be expressed. The average value of Q=0.5(Qs+Qp) and the calculated value of Rx as shown in Table 2 was used to obtain Lx as described in (14). Since the device operates as a resonator, Cx can be calculated using (15) based on Lx and fs.

$$\begin{matrix}{L}_{x} = \frac{{R}_{x} Q}{2 π {f}_{s}} & ( 14 ) \\ {C}_{x} = \frac{1}{{{L}_{x} ( 2 π {f}_{s} )}^{2}} & ( 15 )\end{matrix}$$

TABLE 5
CMOS Surface Acoustic Wave Measured Performance And Equivalent Circuit parameters

| | | | | | Extracted Equivlent | | | | |
|---|---|---|---|---|---|---|---|---|---|
| | Measured | | | | Circuit Parameters | | | | |
| Design | fₛ (GHz) | fₚ (GHz) | Qₛ | Qₚ | Rₓ (kΩ) | Lₓ (μH) | Cₓ (aF) | C_{f} (fF) | Cₒₓ + Cₜ (fF) |
| 1 | 1.03275 | 1.02200 | 33.31 | 44.43 | 10 | 464.91 | 51.66 | 28.0 | 238.27 |
| 2 | 0.93094 | 0.94094 | 46.52 | 86.03 | 15 | 306.39 | 94.57 | 23.5 | 278.00 |
| 3 | 0.60256 | 0.60588 | 0.56 | 284.98 | 10 | 791.82 | 87.98 | 23.5 | 264.75 |

The circuit can be divided into two sets of parallel branches. The impedance of the acoustic branch (Zac) consisting of the extracted values of Rxe, Cxe, Lxe and Cfe is expressed in (16). The parasitic parallel branch containing Rs and (Ct+Cox) calculated from Section IV.A is described as (Zp) in (17). The insertion loss of the circuit is a function of these two impedances Zp and Zac and is shown in (18).

$$\begin{matrix}{Z}_{ac} = \frac{{R}_{xe} + \frac{1}{{sC}_{xe}} + {sL}_{xe}}{{sC}_{fe} ( {R}_{xe} + \frac{1}{{sC}_{xe}} + {sL}_{xe} ) + 1} & ( 16 ) \\ {Z}_{p} = \frac{{R}_{s}}{s ( {C}_{t} + {C}_{ox} ) {R}_{s} + 1} & ( 17 ) \\ IL = - 20 log ( \frac{2 {Z}_{p}}{{Z}_{ac} + 2 {Z}_{p}} ) & ( 18 )\end{matrix}$$

The extracted equivalent circuit values are summarized in Table 5. Calculated values of (Ct+Cox) shown in Table 2 were used as a starting point to obtain Lx, Cx, Rx and Cf. The insertion loss of the extracted equivalent circuit was graphed using MATLAB and compared with both the design equivalent circuit developed in Section IV.A and the measurement results. These graphs were prepared for each resonator and are shown in FIG. 23b, and FIG. 24b respectively. Table 6 shows comparison of design, extracted and measured quality factors for all three resonators.

TABLE 6
COMPARISON OF MEASURED AND EXTRACTED QUALITY
FACTORS

| | Measured | | Extracted | | | Design |
|---|---|---|---|---|---|---|
| | Qₛ | Qₚ | Qₛ | Qₚ | C_{f} (fF) | C_{f} (fF) |
| 1 | 33.31 | 44.43 | 26.98 | 74.97 | 28.0 | 5.6 |
| 2 | 46.52 | 86.03 | 65.70 | 106.65 | 23.5 | 22.4 |
| 3 | 60.56 | 284.98 | 94.75 | 186.00 | 23.5 | 14.9 |

FIG. 23 shows the simulated and measured S21 magnitude transmission characteristics of Resonator 1. From the graph, it can be seen that the design curve shows much lower insertion loss of −31 dB compared to the measured results of −33 dB. The extracted curve shows closer results to the measured curve, having insertion loss of −32.6 dB. The deviation between the measured and design curves can be attributed to the difference between the design Rx=2.16 kOhms and the extracted Rx=10 kOhms. For the design, Rx was calculated based on both the conductance of the device (Gs) and the array reflectivity (Γ). Gs as shown in (1) is highly dependent on the piezoelectric coupling coefficient (κ). Initial values of κ=0.0 17 can serve only as an estimation of the actual value since piezoelectric coupling coefficients are sensitive to variations in processing. It has been shown that K is dependent on khZnO showing maximum κ=0.03 when khZnO=3. As shown in Table 4, khZnO=4.19 for this design where κ can be as low as 0.014, depending on the quality of the sputtered ZnO. Additional losses, and further reduction of Gs is also due to the insufficient reflector height, described earlier in Section V.A. The low quality factor can also be attributed to the small number of reflectors N=39 of this resonator, implemented to minimize the total area of the resonator. FIG. 24b shows much better agreement between the design and measurement results. The measured insertion loss was −35 dB whereas the extracted insertion loss was −36 dB. The extracted Rx=15 kOhms was close to the design Rx=1 3.01 kOhms. The feedthrough capacitance values of both the extracted and design showed a close match to each other, where for the extracted circuit C=23 fF and the design Cf=22.4 fF as shown in Table 6. Similar to Resonator 1, the design Q=29059 for Resonator 2 was much higher than the measured Q of 86.03. The low Q of this resonator was attributed to the low coupling coefficient and insufficient height of the reflector which caused additional losses of the acoustic wave and thus reducing the conductance of the device. The extracted quality factors showed a closer match to the measured quality factor after the extracted Rx was increased to include the additional losses. For this design, L/λ=10.5 and the number of reflectors used was 100, resulting in Γ close to 1, which resulted in a well defined series and parallel resonant frequency.

Resonator 3 shows the best results where the measured insertion loss=−36.406 dB, the extracted insertion loss=37.3618 and the design insertion loss=−36.4395. The extracted Rx=10 kOhms was close to the design Rx=7.56 kOhms. The measured quality factor of Qp=285 is the highest compared to the other designs. This high quality factor is due to the increase in height for the reflector structure, greatly reducing the losses of the propagating acoustic waves. This measurement result indicates that a high quality factor can be achieved even with minimum number of reflectors, where N=33 for this design. It also serves to prove that the quality factor and the array reflectivity are highly dependent on the height of the resonator structure rather than the number of reflectors used. This is in comparison with Resonator 2 which had a lower reflector height but a large number of reflectors and produced a low Q.

This work provides both the implementation of an integrated CMOS surface acoustic wave resonator and the development of its equivalent circuit model to support it. This is significant since it demonstrates that the frequency of surface acoustic waves can controlled using interdigital fingers implemented using inexpensive standard CMOS technology with minimum number of additional post-CMOS micromachining processes. Previous implementations did not utilize standard CMOS process to implement the resonator's interdigital fingers but implemented the fingers using separate deposition steps, resulting in a very high fabrication cost due to the necessity of having very thin and precise interdigital fingers to achieve very high resonant frequencies. The maturity of standard integrated circuit processing technology such as CMOS is very reliable in manufacturing very precise thin metal lines, and for this 0.6 μm CMOS technology used, the minimum metal widths were 0.9 μm, generating a resonant frequency of 1 GHz. Higher frequency resonators can be achieved when smaller CMOS technology feature sizes are used. Currently, the minimum possible CMOS metal feature size is 135 nm and can theoretically create CMOS SAW resonators operating at 7 GHz. Three different resonator designs, operating at different frequencies, 1.02 GHz, 941 MHz and 605 MHz were presented to illustrate the feasibility and the performance of these devices. The measurement results indicate minimum insertion losses in the range −33 dB to −36 dB. The measured quality factor ranged from 33 to 285. Based on the measurement results and the fabrication layers of the device, an equivalent circuit model, tailored specifically to describe the two-port CMOS SAW resonator was developed.

Comparison of the design, extracted and measurement S21 transmission characteristics were presented. It can be seen from these graphs that when losses of the propagating acoustic wave is reduced by increasing the reflector height, the design, extracted and measured results are in accordance with each other. Although the resonators exhibited much lower quality factors than commercial discrete devices which have Qs in the order of 10 000, the quality factors of these devices are much higher than the Qs of integrated LC CMOS resonators which are typically less than 50. LC CMOS resonators are typically used when integrated resonators are required for circuits. The measurement results have also indicated that when the reflector height is increased using stacked metals available in CMOS technology, the quality factor of the device is improved greatly. These designs, although not exhibiting the maximum possible quality factor of the device, was intended as a proof of concept that surface acoustic wave resonators can be implemented using CMOS with the minimum number of post-processes. Further development of this work indicates promising devices such as oscillators and filters for integration with circuits. The quality factor of the device can be further improved by increasing the number of reflectors and implementing methods to improve the piezoelectric coupling coefficient of the device.

### Example

### Second Generation SAW Resonators: RF-CMOS 0.18 μm

RF-CMOS 0.18 μm Resonators

The 0.18 μm RF-CMOS resonators were implemented using the same fabrication process sequence used for the standard CMOS resonators. This process sequence is described in detail elsewhere. The only implementation difference between the RFCMOS resonators and the standard CMOS resonators is that the RF-CMOS resonators were implemented using Metal Top (MT) and Metal 4 (M4) while the standard CMOS resonators were implemented using Metal 2 and Metal 3. MT and M4 are still the top most metal layers for both technologies and results in the same structural layers for both the standard CMOS resonators and the RF-CMOS resonators. Due to this, the equivalent circuit model for the two-port RF-CMOS resonators is the same as the equivalent circuit model for the standard CMOS resonators shown in FIG. 4b.

The 0.6 mm standard CMOS process has minimum metal widths of 0.9 mm, while the 0.18 mm RF-CMOS process has minimum metal widths of 0.28 mm. For our work, which has the objective of realizing an array of CMOS SAW resonators for GSM (850/900/1800/1900) frequencies, metal feature sizes which are smaller than 0.9 mm are required. The IBM CMOS 7RF 6-metal, 1-poly was chosen to implement this array of resonators. With this technology, the minimum allowable metal feature is 0.28 mm. Using v=fᵣl, the highest resonant frequency achieved is fᵣ=3.2 GHz which meets our design specifications. The 6-metal layer stack also enables us to stack the resonator on top of the oscillator, allowing vertical integration and minimizing area. Table 3-7 summarizes the design parameters used for four resonators implemented in RF-CMOS. The 1 of the IDTs were varied in order to produce resonant frequencies of (850/900/1800/1900) MHz. N was increased such that a maximum G was achieved without occupying too much area.

TABLE 3-7
RF-CMOS SAW 2-Port Resonator Design Parameters

| Design | I (mm) | fᵣ (GHZ) | W (mm) | N | L_{g} (mm) | L_{c} (mm) | L (mm) | Lₚ (mm) |
|---|---|---|---|---|---|---|---|---|
| 1 | 4.48 | 0.85 | 134.4 | 80 | 1.12 | 2.24 | 60.5 | 73.965 |
| 2 | 4.20 | 0.90 | 126.0 | 90 | 1.05 | 2.10 | 56.7 | 69.342 |
| 3 | 2.16 | 1.80 | 108.0 | 100 | 2.70 | 1.08 | 37.8 | 35.661 |
| 4 | 2.08 | 1.90 | 124.8 | 100 | 2.60 | 1.04 | 44.72 | 34.341 |

Table 4-4 presents the equivalent circuit model values that were calculated using the formulas given. The parasitic components Cox and Ct were described using formulas respectively. The acoustic wave components, Rx, Cx, Lx and Cf are highly dependent on the array reflectivity (Γ) and were described using (9)(10)(11)(12). Γ was calculated using (5) and affects both Rx and the quality factor (Qs). Comparing Table 4-2 and Table 4-4, it can be seen that the Q factors for the RF-CMOS SAW resonators are much higher than the Q factors for the standard CMOS SAW resonators. This marked improvement in Q factor is due to the increase in κ2. This was achieved by increasing the height of the reflectors to 2.06 μm. Increasing the reflector height to the order of λ helps to reflect most of the acoustic wave since 90% of the SAW energy is within this height [4].

TABLE 4-2
Standard CMOS SAW 1-Port Resonator Design RLC

| | | | | Cₒₓ + | | | | |
|---|---|---|---|---|---|---|---|---|
| | Rₓ | Cₓ | Lₓ | Cₜ | | | fₛ | fₚ |
| Design | (Ω) | (fF) | (μH) | (pF) | Γ | Qₛ | (GHz) | (GHz) |
| 1 | 43 | 12.7 | 1.5 | 105 | 0.83 | 270.25 | 1156 | 1081 |

TABLE 4-4
RF-CMOS SAW 2-Port Resonator Design RLC

| | | Cₓ | | C_{f} | Cₒₓ + Cₜ | | | fₛ | fₚ |
|---|---|---|---|---|---|---|---|---|---|
| Design | Rₓ (Ω) | (aF) | Lₓ (μH) | (fF) | (pF) | Γ | Qₛ | (GHz) | (GHz) |
| 1 | 3347 | 6.05 | 208 | 16.8 | 0.148 | 0.98 | 9148 | 859.36 | 859.54 |
| 2 | 12.4 | 820 | 35.8 | 10/1 | 0.116 | 0.99 | 16884 | 928.58 | 965.61 |
| 3 | 377 | 6.93 | 1100 | 8.4 | 0.139 | 0.99 | 33733 | 1805.6 | 1806.3 |
| 4 | 148 | 15.7 | 457 | 10.0 | 0.206 | 0.99 | 36403 | 1875.0 | 1876.5 |

For our SAW resonators, we have employed CoventorWare®, a commercially available three-dimensional (3-D) FEM modeling software which can accurately model Micro-Electro-Mechanical Systems (MEMS) and microfluidics designs [66]. Using CoventorWare® 3-D physics solvers we can predict both the resonant frequency of the device as well as the amount of static capacitance in the transducers. Formulation of the finite-element analysis model for the SAW resonators using CoventorWare®, were implemented using three steps as follows: description of the fabrication process to build the three-dimensional (3-D) model, meshing and application of voltage and fixed boundary conditions to the piezoelectric model and finally computation and analysis of the results.

Fabrication Process Flow, Mask Definition and Model Generation

For accuracy, the 3-D FEM model was tailored to closely resemble the actual fabrication process used to implement the CMOS SAW resonator structure. Our CMOS SAW resonator structure was realized using the standard AMI 0.6 μm CMOS foundry process followed by a sequence of post-processing steps. This process flow was described as a series of fourteen deposition and etch steps specified in the CoventorWare's Process Editor. Combination of the 2-D mask layouts and the thicknesses information for each layer provided by the manufacturer is used in the process flow . This generates a fairly accurate model of the actual device structure.

An added feature of CoventorWare® is its ability to generate 3-D models from imported layouts done in other layout formats such as CIF, GDS and DXF which are commonly utilized for layouts in IC fabrication [66]. The resonator's fabrication layers and its thicknesses defined in CoventorWare were summarized in Table 4-5.

The first twelve steps mimic the standard CMOS process while the final two steps illustrate the MEMS post-processing steps used to release the transducer fingers and to deposit the piezoelectric layer. The deposition steps were defined as conformal shell depositions which describe a layer that conforms to the profile of the surface and flows over the uneven levels of the materials already present. The etch steps are defined as Straight Cuts in CoventorWare® and can be used to illustrate the removal of material through both wet and dry etching.

TABLE 4-5
CMOS SAW RESONATOR FABRICATION LAYERS

| Number | Step Name | Action | layer Name | Material Name | Thickness | Mask Name |
|---|---|---|---|---|---|---|
| 0 | Substrate | Substrate | Substrate | SILICON | 20 | L49D0 |
| 1 | Stack Material | Conformal Shell | Gate_Oxide | OXIDE | 0.0135 | |
| 2 | Conformal Shell | Conformal Shell | Poly_Heater | POLYSILICON | 0.4 | |
| 3 | Straight Cut | Straight Cut | | | | L25D0 |
| 4 | Stack Material | Conformal Shell | Poly_metal_oxide | OXIDE | 0.6 | |
| 5 | Conformal Shell | Conformal Shell | Metal 1 | ALUMINUM(FILM) | 1.5 | |
| 6 | Straight Cut | Straight Cut | | | | L49D0 |
| 7 | Conformal Shell | Conformal Shell | Inter_metal_oxide | OXIDE | 0.6 | |
| 8 | Stack Material | Stack Material | Metal 2 | ALUMINUM(FILM) | 1.6 | |
| 9 | Straight Cut | Straight Cut | | | | L51D0 |
| 10 | Conformal Shell | Conformal Shell | Inter_metal_oxide | OXIDE | 0.6 | |
| 11 | Stack Material | Stack Material | Metal 3 | ALUMINUM(FILM) | 1.6 | |
| 12 | Straight Cut | Straight Cut | | | | L46D0 |
| 13 | Conformal Shell | Conformal Shell | ZnO | ZnO | 2.4 | |

Simulations using the 3-D FEM model yields information regarding the resonator's modal or natural frequencies as shown in Table 4-8. Table 4-9 summarizes the harmonic analysis simulation results, where the device's displacement response to continuous sinusoidal electrical excitation with frequencies close to the resonant frequency is computed using the dynamic analysis of eigenmodes. The surface acoustic wave behavior in terms of displacement perpendicular to the surface and the amount of charge accumulated in the IDT fingers were analyzed.

TABLE 4-8
CMOS SAW Resonator Modal frequencies

| | Technology 0.18 um RF-CMOS | | | |
|---|---|---|---|---|
| Mode\1 | 4.48 (mm) | 4.2 (mm) | 2.16 (mm) | 2.08 (mm) |
| 1 | 849.9827 MHz | 899.9882 GHz | 1.799967 GHz | 1.899809 GHz |
| 2 | 849.9942 MHz | 899.9960 GHz | 1.799979 GHz | 1.899847 GHz |
| 3 | 850.0081 MHz | 899.9986 GHz | 1.800003 GHz | 1.900030 GHz |
| 4 | 850.0136 MHz | 900.0007 GHz | 1.800017 GHz | 1.900145 GHz |
| 5 | 850.0173 MHz | 900.0069 GHz | 1.800022 GHz | 1.900248 GHz |

TABLE 4-9
CMOS SAW Resonator Harmonic analysis simulation results

| | Technology 0.18 um RF-CMOS | | | |
|---|---|---|---|---|
| L | 4.48 (um) | 4.2 (um) | 2.16 (um) | 2.08 (um) |
| Frequency at | 853.3333 | 899.7777 | 1835.5556 | 1876.6666 |
| Maximum | | | | |
| Displacement | | | | |
| (MHz) | | | | |
| Maximum Dis- | 2.2691 | 8.4168 | 4.7742 | 1.8846 |
| placement in | | | | |
| Z (nm) | | | | |
| Piezoelectric | 0.39195 | 0.49068 | 0.56027 | 0.62265 |
| Charge (pC) | | | | |
| Cₜ (pF) | 0.13065 | 0.16356 | 0.18676 | 0.20755 |
| Cₜₘ (pF) | 0.14112 | 0.11025 | 0.13230 | 0.19656 |

The cross-section of the modeled structure is illustrated in FIG. 30b. Based on this figure, it can be seen that there are four distinct structures in the CMOS SAW resonator structure. The resonator transducer fingers generate the acoustic waves and were constructed using Metal 2. The reflectors confine the acoustic waves within the cavity and were built using both Metal 2 and Metal 3. The polysilicon heater provides a method of maintaining the temperature of the resonator. The ground shield has dual purpose of eliminating electromagnetic feedthrough and to ensure even temperature distribution thorughout the metal plate and thus the resonator. The definition of the piezoelectric zinc-oxide material properties in CoventorWare® is detailed in Appendix B.

Mesh Specification and Generation

The SAW resonator structure consists of thin and long geometries which form the transducer fingers and reflectors. To discretize this type of geometry, where all the model faces are planar and join at 90 degree angles, the Manhattan brick mesh model was chosen. The entire model structure was divided into linear hexahedral or 8-node brick finite elements. The resonator structural layers were partitioned into two regions, defined by their mesh density to ease computation and analysis. Coarse Manhattan brick meshing was applied to the first region or the substrate. Mesh refinement was applied to the region of interest, which contains the transducers and reflectors and where the acoustic displacement occurs.

TABLE 4-6
CMOS SAW RESONATOR MESH MODEL ASPECT RATIOS

| | | | | Element | |
|---|---|---|---|---|---|
| | | | | Size | Aspect |
| Region | Layer | Mesh | Mesh Type | (X, Y, Z) | Ratio |
| 1 | Substrate | Coarse | Manhattan Bricks | 50, 50, 50 | 1.16 |
| 2 | Poly_Metal | Fine | Manhattan Bricks | 2, 4, 2 | 9.60 |
| | Oxide | | | | |
| 3 | Metal 1 | Fine | Manhattan Bricks | 2, 4, 2 | 5.23 |
| 4 | Intermetal | Fine | Manhattan Bricks | 2, 4, 2 | 9.60 |
| | Oxide | | | | |
| 5 | Metal 2 | Fine | Manhattan Bricks | 2, 4, 2 | 5.60 |
| 6 | Zinc Oxide | Fine | Manhattan Bricks | 2, 4, 2 | 4.98 |

To reduce computation time, the aspect ratio which is defined as the width over length of each element has to be less than 10. This was verified by performing a mesh quality analysis. The defined meshed regions, its mesh type, element sizes and aspect ratios of the resonator are shown in Table 4-6.

Measurement and Characterization of 2^{nd} Generation SAW Resonators

The next CMOS SAW resonator chip had been designed to achieve much higher RF resonant frequencies of 850 MHz, 900 MHz, 1.8 GHz and 1.9 GHz respectively. The microscope image of the four resonators fabricated on the IBM RF-CMOS 0.18 mm technology is shown in FIG. 36b. The periodic distance of the IDTs (λ) were designed to achieve these frequencies and was set to be 4.48 μm, 4.20 μm, 2.16 μm and 2.08 μm respectively. FIGS. 43 b, 44b, 45b, and 46b illustrate the S21 transmission measurement results.

Summary of Results

The measurement results obtained for all the resonators indicate that surface acoustic wave resonators can be successfully be implemented using the CMOS process.

Two different process technologies had been used to fabricate these resonators, namely, 0.6 μm standard CMOS and 0.18 μm RF-CMOS. The resonators had measured resonant frequencies ranging from 200 MHz to 3.2 GHz. The first CMOS SAW resonator was a single port resonator, with resonant frequency of 1 GHz and quality factor of 90. To enhance the performance of the resonators, the reflector height of the second set of resonator was increased to improve the efficiency of the device. This was done by placing an additional stack of metal layer on the existing reflectors to reflect the entire wave within x height of the acoustic wave. Better performance characteristics were obtained in this second batch of CMOS SAW resonators with quality factor of 280. Three resonators were successfully implemented using this 0.6 μm CMOS technology with resonant frequencies of 600 MHz, 900 MHz and 1 GHz. The final set of resonators was an attempt to fabricate resonators with resonant frequencies of 1.8 GHz and 1.9 GHz using 0.18 μm IBM RF-CMOS technology. Due to the increase in acoustic wave velocities at higher frequencies, the measured resonators showed much higher resonant frequencies of 850 MHz, 992 MHz, 2.85 GHz and 3.12 GHz respectively. Similar characteristics to the standard CMOS resonators were observed in terms of quality factors where these IBM RF-CMOS resonators had quality factors in the range of 40 to 300.

Quality Factors

The series and parallel resonant frequencies and quality factors can be obtained from the S21 transmission measurement results. These values are summarized in Table 6-11.

TABLE 6-11
RF-CMOS SAW RESONATOR SERIES AND PARALLEL
RESONANT FREQUENCIES AND QUALITY FACTORS

| Resonator | fₛ (GHz) | fₚ (GHz) | Qₛ | Qₚ | Phase Shift |
|---|---|---|---|---|---|
| 1 | 0.8461 | 0.8521 | 94.01 | 94.67 | 147 |
| 2 | 0.9900 | 1.0201 | 61.95 | 100.01 | 100 |
| 3 | 2.8560 | 2.8200 | 71.40 | 201.43 | 85.2 |
| 4 | 3.1190 | 3.0550 | 37.13 | 254.58 | 94.12 |

It can be seen in Table 6-11 that the quality factor of these devices fabricated using RF-CMOS 0.18 μm are comparable to the ones fabricated in CMOS 0.6 μm technology and range between 37 to 254. More distinct resonant frequencies were observed in the lower frequencies (850 MHz and 990 MHz) resonators as compared to the higher frequencies resonators (2.85 GHz and 3.112 GHz). As observed from Table 6-11, FIG. 45b and 46b, the higher frequency resonators are much more susceptible to harmonics and series quality factor degradation.

Performance degradation at higher frequencies (in the GHz range) are typical in acoustic wave devices even when fabricated on piezoelectric substrates such as sapphire, lithium niobate, GaAs and tantalate. Specific to ZnO, this data is in agreement with the findings of Price and Wilkinson, where it has been shown that SAW propagation losses are frequency dependent and increase with the increase in frequency.

The less distinct resonant series resonant frequencies observed in both the 2.85 GHz and 3.12 GHz resonators are also due to the degradation of the reflectivity, (r). This coefficient, defined in (4.4) is highly dependent on the electromechanical coupling coefficient κ. Although both of the 2.85 GHz and 3.12 GHz resonators were designed to be synchronously spaced, due to the degradation of κ, measurement results indicate that these resonators are optimally spaced. Optimally spaced resonators can be recognized by their lower insertion losses and reduced series quality factors.

As observed in FIGS. 43b and 44b, the insertion losses of Resonator 1 and 2 are very high, ranging from 50 dB to 85 dB. The high losses are due to the impedance mismatch, which are illustrated by the measurements of the S11 and S22 reflection characteristics. Since the devices are symmetrical, the S11=S22 and the measurement results for Resonator 1 is shown in FIG. 47b (left) and for Resonator 2 is shown in FIG. 47b (right) respectively.

The measurement of the reflection characteristics that the device has imaginary impedances in the range of −150Ω to −250Ω and the real impedances in the range of 8Ω to −20Ω. In contrast, the measured insertion losses of Resonator 3 and Resonator 4 are much lower, ranging from 45 dB to 65 dB. This indicates that both Resonators 3 and 4 have better impedance matching. This assumption was proven by measurements of the reflection characteristics or S11 and S22 for both Resonator 3 and Resonator 4 as shown in FIG. 48b.

The real impedances were measured to be in the range of 1.627Ω to 8.4947Ω. The imaginary impedances were measured to be in the range of −130Ω to −102Ω. As observed in Table 6-7 with the different periodic distance, λ of the SAW resonator fabricated in the 0.6 μm CMOS process, the acoustic wave velocity is not constant as theoretically assumed during the design of the resonators. The same phenomenon was observed in the SAW resonators fabricated using 0.18 μm RF-CMOS process. This effect was even more pronounced as shown in Table 6-12 which shows an almost linear relationship of the SAW velocity with the series resonant frequency.

TABLE 6-12
EXTRACTED SURFACE ACOUSTIC WAVE
VELOCITIES AT DIFFERENT λ

| λ (μm) | Measured fₛ | Extracted SAW velocity |
|---|---|---|
| 4.48 | 0.8455 GHz | 3788 m/s |
| 4.20 | 0.9922 GHz | 4167 m/s |
| 2.16 | 2.8500 GHz | 6156 m/s |
| 2.08 | 3.1190 GHz | 6488 m/s |

The measured value of the surface acoustic wave velocity was calculated using v=fs.λ, where v is the velocity of the SAW, fs is the series resonant frequency and l is the periodic distance between the IDTs. It can be seen from Table 6-12 that the resonators operating at higher frequencies have higher acoustic wave velocities. This phenomenon also caused the measured resonant frequencies to be shifted from the originally designed resonant frequencies of 850 MHz, 900 MHz, 1.8 GHz and 1.9 GHz. Similar to the method implemented for the 0.6 μm CMOS, the equivalent circuit parameters were calculated for the IBM RF-CMOS SAW resonators based on the S21 transmission measurements. The summary of these values is shown in Table 6-13.

TABLE 6-13
RF-CMOS SAW 2-PORT RESONATOR EXTRACTED RLC

| Resonator | Rₓ (kΩ) | Cₓ (aF) | Lₓ (mH) | Cᵣ (fF) | Cₒₓ + Cₜ (pF) |
|---|---|---|---|---|---|
| 1 | 3.347 | 6.05 | 4.715 | 85 | 0.148 |
| 2 | 3.024 | 820 | 0.0313 | 17 | 7.74 |
| 3 | 20.0 | 6.93 | 0.41 | 0.15 | 0.0695 |
| 4 | 31.94 | 15.9 | 0.197 | 2.44 | 0.7845 |

It can be seen from the Table 6-13 that Resonators 3 and 4 have much higher values of Rx which is reflected in the lower series quality factor of both resonators. Due to the change in the measured acoustic velocity compared to the designed value of 3800 m/s, which shifts the measured series resonant frequency, the extracted value of Lxe is different from the design Lx values.

The following references are incorporated herein in their entirety. Their numbering is reflected in the reference numerals used herein.

### REFERENCES

[1] W. Buff, M. Rusko, E. Goroll, J. Ehrenpfordt, T. Vandahl, “Universal pressure and temperature SAW sensor for wireless applications,” Ultrasonics Symposium, 1997. Proceedings., 1997 IEEE, vol. 1, no. pp. 359-362 vol. 1, Oct. 5-8, 1997

[2] P. Smole, W. Ruile, C. Korden, A. Ludwig, E. Quandt, S. Krassnitzer, P. Pongratz, “Magnetically tunable SAW-resonator,” Frequency Control Sympposium and PDA Exhibition Jointly with the 17th European Frequency and Time Forum, 2003. Proceedings of the 2003 IEEE International , vol., no. pp. 903-906, May 4-8, 2003

[3] A. Pohl, G. Ostermayer, F. Seifert, “Wireless sensing using oscillator circuits locked to remote high-Q SAW resonators,” Ultrasonics, Ferroelectrics and Frequency Control, IEEE Transactions on, vol. 45, no. 5 pp. 1161-1168, September 1998

[4] T. Nomura, R. Takebayashi, A. Saitoh, “Chemical sensor based on surface acoustic wave resonator using Langmuir-Blodgett film”, “Ultrasonics, Ferroelectrics and Frequency Control, IEEE Transactions on, vol. 45, no. 5pp. 1261-1265, September 1998.

[5] S. Datta, “Resonators”, Prentice Hall, 1986, Ch. 10, pp. 225-239.

[6] Ruby, R. C.; Bradley, P.; Oshmyansky, Y.; Chien, A.; Larson, J. D., III, “Thin film bulk wave acoustic resonators (FBAR) for wireless applications,” Ultrasonics Symposium, 2001 IEEE, vol. 1, no. pp. 813-821 vol. 1, 2001

[7] J. H. Visser, “Surface acoustic wave filter in ZnO—SiO2-Si layered structures: Design, technology and monolithic integration with electronic circuitry,” Ph.D. dissertation, Delft University of Technology. Delft, the Netherlands, December 1989.

[8] M. J. Vellekoop, G. W. Lubking, A. Venema, “Acoustic-wave based monolithic microsensors”, Invited, Proc. IEEE Ultrasonics Symposium, Cannes, France, (1994), pp. 565-574.

[9] A. G. Baca, E. J. Heller, V. M. Hietala, S. A. Casalnuovo, G. C. Frye-Mason, J. F. Klem, T. J. Dummond, “Development of a GaAs monolithic surface acoustic wave integrated circuit”, IEEE J. Solid-State Circuits, vol. 34. no. 9, 1999

[10] A. N. Nordin, M. E. Zaghloul, “Design and Implementation of a 1 GHz Resonator Utilizing Surface Acoustic Wave,” presented at the Int. Sym. Circuits and Systems, Kos, Greece, 2006.

[11] D. P. Morgan, “Analysis of Interdigital Transducers,” Surface-Wave Devices for Signal Processing, New York: Elesevier Science, 1985, Ch. 4, pp. 57-105.

[12] P. T. M. van Zeijl, “Fundamental aspects and design of an FM upconversion receiver front-end with on-chip SAW filters,” Ph.D. dissertation, Delft University of Technology. Delft, Netherlands, February 1990.

[13] S. Datta, B. J. Hunsinger, “An analytical theory for the scattering of surface acoustic waves by a single electrode in a periodic array on a piezoelectric substrate”, J. Appl. Phys, vol. 51, pp. 4817-4823, 1980

[14] O. Tigli, M. E. Zaghloul, “Design and Fabrication of a Novel SAW Bio/Chemical Sensor in CMOS”, in 2005 Proc. IEEE Sensors Conf., pp. 137-140.

[15] M. J. Vellekoop, “A Smart Lamb-Wave Sensor System”, Ph.D. dissertation, Delft University of Technology. Delft, the Netherlands, December 1989.

[16] J Zhu, N W Emanetoglu, Y Chen, B V Yakshinskiy, Y Lu, “Wet-Chemical Etching of (112 □0) ZnO Films”, Journal of Electronic Materials; June 2004, vol. 33, no. 6, pp. 556-559.

[17] http://www.amis.com/pdf/C5_process_spec.pdf

[18] http://www.coventor.com

[19] http://www.cmicro.com/index.cfm/fuseaction/pg.view/pID/1172IEEE

[20] Standard definitions and methods of measurement for piezoelectric vibrators, ANSI/IEEE Standard 177, New York, N.Y., 1966.

[21] IEEE Standard on Piezoelectricity, ANSI/IEEE Standard 176, New York, N.Y., 1987.

[25] Iwai H., 2000, “CMOS technology for RF application”, PROC. 22nd INTERNATIONAL CONFERENCE ON MICROELECTRONICS (MIEL ZOOO), VOL 1, NI$, SERBIA, 14-17 May, 2000, 1, pp. 27-34 vol. 21.

[26] Hassan H., Anis M., Elmasry M., 2004, “Impact of technology scaling on RF CMOS”, IEEE SOC Conference, pp. 97-101.

[27] Burghartz J. N., 2001, “Tailoring logic CMOS for RF applications”, VLSI Technology Systems and Applications, pp. 150-153.

[28] Shi B., 2001, “Challenges in RF analog integrated circuits”, ASIC, IEEE Proceedings. 4th International Conference on, pp. 800-805.

[29] Hiroshi I., 2004, “RF CMOS technology”, Radio Science Conference, IEEE Proceedings Asia-Pacific, pp. 296-298.

[30] Huang Q., Piazza F., Orsatti P., Ohguro T., “The impact of scaling down to deep submicron on CMOS RF circuits,” Solid-State Circuits, IEEE Journal of, 1998, 33, (7), pp. 1023-1036.

[31] Steyaert M. S. J., De Muer B., Leroux P., Borremans M., Mertens K., “Low-voltage low-power CMOS-RF transceiver design,” Microwave Theory and Techniques, IEEE Transactions on, 2002, 50, (1), pp. 281-287.

[32] Lin T. H., Sanchez H., Rofougaran R., Kaiser W. J., 1998, “Micropower CMOS RF components for distributed wireless sensors”, Radio Frequency Integrated Circuits (RFIC) Symposium, IEEE, pp. 157-160.

The references recited herein are incorporated herein in their entirety, particularly as they relate to teaching the level of ordinary skill in this art and for any disclosure necessary for the commoner understanding of the subject matter of the claimed invention. It will be clear to a person of ordinary skill in the art that the above embodiments may be altered or that insubstantial change may be made without departing from the scope of the invention. Accordingly, the scope of the invention is determined by the scope of the following claims and their equitable Equivalents.

1. A SAW resonator fabricated using RF-CMOS technology, wherein the SAW resonator is capable of a resonant frequency of from about 1 GHz to about 3.12 GHz.

2. The SAW resonator of claim 1, further comprising wherein the SAW resonator has a quality factor about 285 or greater.

3. The SAW resonator of claim 1, further comprising wherein the SAW resonator has interdigital transducers and reflectors having submicron width.

4. The SAW resonator of claim 1, further comprising wherein the SAW resonator is miniature having length and width dimensions of less than about 500 μm.

5. The SAW resonator of claim 1, further comprising wherein the SAW resonator is miniature having length and width dimensions of less than about 300 μm.

6. The SAW resonator of claim 1, further comprising wherein the SAW resonator has integrated, stacked, submicron reflectors which provides significant increase in quality factors of the device.

7. The SAW resonator of claim 1, further comprising wherein the SAW resonator has an integrated ground shield layer underneath the entire device to isolate it from electromagnetic feed-through and undesired coupling through the Si substrate.

8. The SAW resonator of claim 1, further comprising wherein the SAW resonator has an integrated heat-control structure consisting of a polysilicon heater placed underneath the ground shield layer. The ground shield has dual purpose of electromagnetic feedthrough and as a heat distributing plate.

9. A process for fabricating a GHz-capable SAW resonator device using commercial RF-CMOS technology, comprising: i) patterning the SAW resonator's electrodes during RF-CMOS fabrication, and ii) removal of the double passivation layers, SiN and SiO₂, and iii) depositing piezoelectric material on top of SAW resonator's electrodes, and iv) performing wet-etching such that the piezoelectric material covers only the resonator region wherein a reactive ion etch releases the SAW resonator electrodes from the dielectric layer before the piezoelectric material is deposited, wherein the SAW resonator is capable of a resonant frequency of from about 1 GHz to about 3.12 GHz.

10. The process of claim 9, wherein the piezoelectric material is ZnO.

11. The process of claim 9, wherein the wet-etching uses a very dilute acid solution.

12. The process of claim 11, wherein the very dilute acid solution is a two acid mixture, wherein each acid of the two acid mixture is selected from the group consisting of acetic acid, hydrochloric acid, and phosphoric acid.

13. The process of claim 11, wherein the CMOS process sequence includes fabricating an isolation structure under the interdigital transducers and reflectors of the SAW resonator, wherein the isolation structure comprises a single, integrated metal shield and provides isolation from electromagnetic feed-through.

14. A SAW device made by the process of claim 9.

15. An integrated circuit chip having the SAW resonator of claim 1 as an on-chip component.

16. The chip of claim 15, wherein the chip is a microprocessor.

17. The chip of claim 15, wherein the chip is a programmable integrated circuit.

18. The chip of claim 15, wherein the chip is a microelectromechanical system (MEMS).

19. The chip of claim 15, wherein the chip is a nanoelectromechanical system (NEMS).

20. The integrated circuit chip of claim 15, fuirther comprising an embedded heater structure.

21. An LC circuit which comprises the SAW resonator of claim 1 and an amplifier on the same chip.

22. A local oscillator, which comprises the LC circuit of claim 21 connected to a Pierce oscillator.
